(19) United States
(12) Patent Application Publication
(10) Pub. No.: US 2024/0006674 A1
(43) Pub. Date: Jan. 4, 2024

(54) STORAGE BATTERY SYSTEM, SECONDARY BATTERY, AND OPERATION METHOD OF STORAGE BATTERY SYSTEM

(71) Applicant: SEMICONDUCTOR ENERGY LABORATORY CO., LTD., Atsugi-shi, Kanagawa-ken (JP)

(72) Inventors: Takeshi OSADA, Isehara, Kanagawa (JP); Takayuki IKEDA, Atsugi, Kanagawa (JP); Yosuke TSUKAMOTO, Atsugi, Kanagawa (JP); Hiroki INOUE, Atsugi, Kanagawa (JP); Kiyotaka KIMURA, Isehara, Kanagawa (JP); Shunsuke SATO, Yokohama, Kanagawa (JP); Toshiki MIZUGUCHI, Atsugi, Kanagawa (JP)

(21) Appl. No.: 18/265,116

(22) PCT Filed: Dec. 2, 2021
(86) PCT No.: PCT/IB2021/061208

§ 371 Date: Jun. 2, 2023

(30) Foreign Application Priority Data
Dec. 16, 2020 (JP) 2020-208780

(51) Int. Cl. H01M 10/48; H01M 10/42; G01R 31/367

(52) U.S. Cl. CPC H01M 10/48; H01M 10/425; G01R 31/367; H01M 2010/4278

(57) ABSTRACT

A sensor capable of detecting local expansion or the like is provided, and a storage battery system including a safety system such as the sensor and a secondary battery is provided. The storage battery system includes a first secondary battery and a second secondary battery each including an exterior body holding an electrolyte solution, a positive electrode, and a negative electrode; a sensor member provided to be in contact with part of the exterior body; and a detection circuit controlling the sensor member. The first secondary battery includes a memory unit storing data collected with gas introduction into the second secondary battery, a learning model constructed on the basis of the data, and an estimated value obtained using the learning model; and a unit providing information based on the estimated value.

### TECHNICAL FIELD

One embodiment of the present invention relates to a storage battery system, a secondary battery, and an operation method of the storage battery system.

One embodiment of the present invention is not limited to the above technical field, and one embodiment of the present invention relates to a semiconductor device, a display device, a light-emitting device, a lighting device, an electronic device, an operation method thereof, or a fabrication method thereof.

### BACKGROUND ART

Secondary batteries typified by lithium-ion secondary batteries are essential for a modem society as energy sources that can be used repeatedly. In particular, secondary batteries for mobile electronic devices have been required to have high safety.

A secondary battery includes an electrolyte solution in addition to a positive electrode and a negative electrode, and the electrolyte solution is sometimes decomposed by deterioration or the like. A gas generated by the decomposition of the electrolyte solution causes expansion of the secondary battery. In addition, a decomposed product generated by the decomposition of the electrolyte solution might cause, in addition to the expansion, an increase in internal resistance of the secondary battery. The expansion or the increase in internal resistance degrades the safety of the secondary battery.

In order to inhibit the expansion or the like of the secondary battery, a safety system is incorporated into the secondary battery (see Patent Document 1, for example).

### REFERENCE

### Patent Document

[Patent Document 1] Japanese Published Patent Application No. 2018-137078

### SUMMARY OF THE INVENTION

### Problems to be Solved by the Invention

Patent Document 1 discloses a safety system against expansion of a secondary battery, which has a structure where a metal film is provided for a laminated film storing an electrolyte solution to detect a change in capacitance due to an internal pressure increase. Such a safety system is required to have higher detection sensitivity.

In view of this, an object of one embodiment of the present invention is to provide a storage battery system including a sensor with high detection sensitivity and a secondary battery.

Note that the description of these objects does not preclude the existence of other objects. One embodiment of the present invention does not have to achieve all the objects. Other objects can be derived from the description of the specification, the drawings, and the claims.

### Means for Solving the Problems

In view of the above, one embodiment of the present invention is a storage battery system including a first secondary battery and a second secondary battery each including an exterior body holding an electrolyte solution, a positive electrode, and a negative electrode; a sensor member provided to be in contact with part of the exterior body; and a detection circuit controlling the sensor member. The first secondary battery includes a memory unit storing data collected with gas introduction into the second secondary battery, a learning model constructed on the basis of the data, and an estimated value obtained using the learning model; and a unit providing information based on the estimated value.

One embodiment of the present invention is a storage battery system including a first secondary battery and a second secondary battery each including an exterior body holding an electrolyte solution, a positive electrode, and a negative electrode; a sensor member provided to be in contact with part of the exterior body; and a detection circuit controlling the sensor member. The first secondary battery includes a memory unit storing an expansion amount collected with gas introduction into the second secondary battery, a learning model constructed on the basis of the expansion amount, an estimated value obtained using the learning model; and a unit providing information based on the estimated value.

One embodiment of the present invention is a secondary battery including an exterior body holding an electrolyte solution, a positive electrode, and a negative electrode; a sensor member provided to be in contact with part of the exterior body; and a detection circuit controlling the sensor member.

In one embodiment of the present invention, the sensor member is preferably a film-like or string-like piezoelectric element.

One embodiment of the present invention is a method for operating a storage battery system that includes a first secondary battery and a second secondary battery each including an exterior body holding an electrolyte solution, a positive electrode, and a negative electrode; a sensor member provided to be in contact with part of the exterior body; and a detection circuit controlling the sensor member. The method includes a step of introducing a gas into the second secondary battery, a step of collecting data on the second secondary battery, a step of constructing a learning model on the basis of the data, a step of storing an estimated value using the learning model, and a step of providing information based on the estimated value to the first secondary battery.

One embodiment of the present invention is a method for operating a storage battery system that includes a first secondary battery and a second secondary battery each including an exterior body holding an electrolyte solution, a positive electrode, and a negative electrode; a sensor member provided to be in contact with part of the exterior body; and a detection circuit controlling the sensor member. The method includes a step of introducing a gas into the second secondary battery and expanding the second secondary battery, a step of collecting an expansion amount of the second secondary battery, a step of constructing a learning model on the basis of the expansion amount, a step of storing an estimated value using the learning model, and a step of providing information based on the estimated value to the first secondary battery.

In one embodiment of the present invention, the electrolyte solution preferably includes an organic electrolyte solution.

In one embodiment of the present invention, the sensor member is preferably a film-like or string-like piezoelectric element.

### Effect of the Invention

The present invention can provide a storage battery system including a sensor with high detection sensitivity and a secondary battery.

Note that the description of these effects does not preclude the existence of other effects. Note that one embodiment of the present invention does not need to have all the effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1D are diagrams illustrating secondary batteries of embodiments of the present invention.

FIG. 2A and FIG. 2B are diagrams illustrating a sensor member and a detection circuit of embodiments of the present invention.

FIG. 3 is a diagram showing a fabrication process of a secondary battery of one embodiment of the present invention.

FIG. 4A and FIG. 4B are a flow chart and a structure example of one embodiment of the present invention.

FIG. 5A and FIG. 5B are diagrams illustrating a structure example of neural network processing of one embodiment of the present invention.

FIG. 6 is a diagram illustrating crystal structures of a positive electrode active material of one embodiment of the present invention.

FIG. 7A and FIG. 7B are diagrams illustrating a positive electrode active material layer of one embodiment of the present invention.

FIG. 8 is a diagram illustrating a fabrication process of a positive electrode active material of one embodiment of the present invention.

FIG. 9 is a diagram showing a fabrication process of a positive electrode active material of one embodiment of the present invention.

FIG. 10 is a diagram showing a fabrication process of a positive electrode active material of one embodiment of the present invention.

FIG. 11 is a diagram showing a fabrication process of a positive electrode active material of one embodiment of the present invention.

FIG. 12A to FIG. 12C are diagrams illustrating a secondary battery of one embodiment of the present invention.

FIG. 13A to FIG. 13D are diagrams illustrating secondary batteries of embodiments of the present invention.

FIG. 14A and FIG. 14B are diagrams illustrating a secondary battery of one embodiment of the present invention.

FIG. 15A to FIG. 15D are diagrams illustrating secondary batteries of embodiments of the present invention.

FIG. 16A and FIG. 16B are diagrams illustrating secondary batteries of embodiments of the present invention.

FIG. 17 is a diagram illustrating a secondary battery of one embodiment of the present invention.

FIG. 18A to FIG. 18H are diagrams illustrating electronic devices of embodiments of the present invention.

FIG. 19A to FIG. 19C are diagrams illustrating an electronic device of one embodiment of the present invention.

FIG. 20 is a diagram illustrating electronic devices of embodiments of the present invention.

FIG. 21A to FIG. 21D are diagrams illustrating electronic devices of embodiments of the present invention.

FIG. 22A to FIG. 22C are diagrams illustrating electronic devices of embodiments of the present invention.

FIG. 23A to FIG. 23C are diagrams illustrating vehicles of embodiments of the present invention.

FIG. 24 is a diagram illustrating a storage battery system of one embodiment of the present invention.

### MODE FOR CARRYING OUT THE INVENTION

Examples of embodiments of the present invention will be described in detail below with reference to the drawings and the like. Note that the present invention should not be interpreted as being limited to the examples of embodiments given below. Embodiments of the invention can be changed unless it deviates from the spirit of the present invention.

In this specification and the like, the Miller index is used for the expression of crystal planes and crystal orientations. An individual plane that shows a crystal plane is denoted by “( )”. In the crystallography, a bar is placed over a number in the expression of crystal planes, crystal orientations, and space groups; in this specification and the like, because of format limitations, crystal planes, crystal orientations, and space groups are sometimes expressed by placing “−” (a minus sign) in front of the number instead of placing a bar over the number.

In this specification and the like, a theoretical capacity of a positive electrode active material refers to the amount of electricity obtained when all lithium that can be inserted and extracted and is contained in the positive electrode active material is extracted. For example, the theoretical capacity of LiCoO₂ is 274 mAh/g, the theoretical capacity of LiNiO₂ is 274 mAh/g, and the theoretical capacity of LiMn₂O₄ is 148 mAh/g.

In this specification and the like, the remaining amount of lithium that can be inserted into and extracted from a positive electrode active material is represented by x in a compositional formula, e.g., x in LixCoO₂ or x in LiₓMO₂. In the case of a positive electrode active material in a secondary battery, x can be represented by (theoretical capacity−charge capacity)/theoretical capacity. For example, in the case where a secondary battery using LiCoO₂ as a positive electrode active material is charged to 219.2 mAh/g, it can be said that the positive electrode active material is represented by Li_{0.2}CoO₂ or x=0.2. Small x in LixCoO₂ means, for example, 0.1<x≤0.24.

Lithium cobalt oxide to be used for a positive electrode, which has been appropriately synthesized and almost satisfies the stoichiometric proportion, is LiCoO₂, and the occupancy rate x of Li in the lithium sites is 1. For a secondary battery after its discharge ends, it can be said that lithium cobalt oxide is LiCoO₂ and x=1. In a lithium-ion secondary battery using the lithium cobalt oxide, a discharge voltage rapidly decreases before the voltage reaches 2.5 V; thus, a state where the voltage is lower than or equal to 2.5 V (in the case of a lithium counter electrode) at a current of 100 mA/g is regarded as the end of discharging.

### Embodiment 1

In this embodiment, a secondary battery and a sensor provided in the secondary battery are described. The sensor includes a sensor member, a detection circuit electrically connected to the sensor member, and the like.

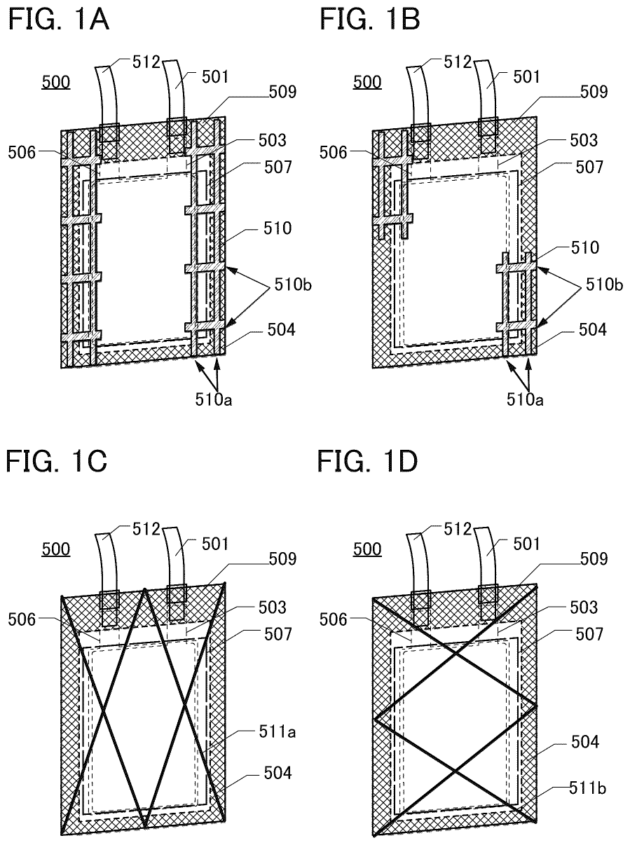

FIG. 1A illustrates a laminated secondary battery 500. The secondary battery 500 includes a positive electrode tab 501, a negative electrode tab 512, a positive electrode 503 electrically connected to the positive electrode tab 501, and a negative electrode 506 electrically connected to the negative electrode tab 512. A separator 507 is positioned between the positive electrode 503 and the negative electrode 506. The area of the separator 507 is preferably larger than the area of the positive electrode 503 and the area of the negative electrode 506. The separator 507, the positive electrode 503, and the negative electrode 506 are held in an exterior body 509, and thus are shown by dashed lines in FIG. 1A.

In this embodiment, the exterior body 509 is provided with a sensor member 510. The sensor member 510 preferably includes a piezoelectric element. The piezoelectric element has a structure where a piezoelectric substance is interposed between electrodes. The piezoelectric element has high responsiveness, moves smoothly, and can move precisely, and thus is suitable for the sensor member 510.

In this embodiment, the sensor member 510 preferably has a thin-film shape. For example, the thickness of the sensor member 510 is preferably smaller than the thickness of the exterior body 509. The film-like sensor member 510 is preferable because it is less likely to be peeled off due to expansion and contraction (referred to as expansion or the like) of the exterior body 509. The film-like sensor member 510 can sense deformation of the exterior body 509 due to expansion or the like. Specifically, deformation of the exterior body 509 applies a pressure to the sensor member 510, whereby an electric signal such as a current or a voltage can be acquired from the sensor member 510. The electric signal can be generated by the detection circuit or the like electrically connected to the sensor member 510.

The exterior body 509 includes an adhesive region 504 that is attached by thermocompression bonding or the like. The adhesive region 504 is positioned along sides of the exterior body 509, typically positioned along the four sides of the exterior body 509. The sensor member 510 illustrated in FIG. 1A is provided in a region overlapping with the adhesive region 504 and the vicinity thereof. Deformation of the exterior body 509 due to expansion or the like is easily recognized in the adhesive region 504 and the vicinity thereof. In FIG. 1A, the sensor member 510 is provided along two sides of the exterior body 509, among the regions overlapping with the adhesive region 504 and the vicinity thereof. The two sides are illustrated as sides along the major axis of the exterior body 509 in FIG. 1A; however, the two sides may be sides along the minor axis of the exterior body 509 as long as the sensor member 510 is positioned to overlap with the adhesive region 504 and the vicinity thereof.

Expansion or the like of the exterior body 509 applies a pressure to the sensor member 510, whereby an electric signal can be acquired with the use of the detection circuit or the like and the expansion or the like of the secondary battery 500 can be recognized. Thus, providing the sensor member 510 of the present invention in part of the exterior body 509 not in the entire exterior body 509 can increase the detection sensitivity.

The top surface of the sensor member 510 preferably has a belt-like shape. Furthermore, the top surface shape of the sensor member 510 preferably includes a first region 510a extending in the major axis direction of the exterior body 509 and a second region 510b extending in the minor axis direction. An interval between the first region 510a and another first region 510a adjacent thereto is preferably greater than or equal to 0.1 mm and less than or equal to 1 cm, further preferably greater than or equal to 1 mm and less than or equal to 5 mm, and an end portion of the adhesive region 504 is preferably positioned between the first region 510a and the adjacent first region 510a. An interval between the second region 510b and another second region 510b adjacent thereto is preferably greater than the interval between the first region 510a and another first region 510a adjacent thereto, and for example, is greater than or equal to 0.5 mm and less than or equal to 5 cm, preferably greater than or equal to 1 cm and less than or equal to 2 cm. A pressure is easily applied to the sensor member 510 including the first region 510a and the second region 510b due to expansion or the like of the exterior body 509; thus, the sensor member 510 has a top surface shape with which deformation of the exterior body 509 is easily recognized.

The sensor members 510 illustrated in FIG. 1B are positioned in a smaller region than those in FIG. 1A. For example, in regions in two sides of the exterior body 509, the sensor members 510 are provided in an upper portion and a lower portion that are diagonally opposite to each other. The other structures are similar to those in FIG. 1A.

The sensor member includes at least a piezoelectric element, and the top surface shape or the like is not limited to that in FIG. 1A and FIG. 1B. For example, the sensor member that does not include the first region 510a and includes a plurality of second regions 510b may be employed. Alternatively, the sensor member that does not include the second region 510b and includes a plurality of first regions 510a may be employed.

The arrangement of the sensor members 510 is also not limited to that in FIG. 1A and FIG. 1B. Various arrangement other than the above can be employed as long as the sensor members 510 are arranged to overlap with the adhesive region 504 and the vicinity thereof. Note that the sensor member 510 is preferably in contact with part of the exterior body 509, in which case a pressure due to deformation is easily applied.

The secondary battery 500 illustrated in FIG. 1C is different from that in FIG. 1A in including a sensor member 511a. The secondary battery 500 illustrated in FIG. 1D is different from that in FIG. 1A in including a sensor member 511b. Each of the sensor member 511a and the sensor member 511b has a string-like external shape, and thus is referred to as a string-like sensor member. The other structures are similar to those in FIG. 1A.

The string-like sensor member can be placed to be hung on part of the secondary battery 500, and the sensor member 511b illustrated in FIG. 1D is different from the sensor member 511a illustrated in FIG. 1C in the position where the sensor member is hung on part of the secondary battery 500.

The sensor member 511a and the sensor member 511b each include at least a piezoelectric element, and the top surface shape or the like is not limited to that in FIG. 1C and FIG. 1D.

Arrangement of the sensor members 511a and the sensor members 511b is also not limited that in FIG. 1C and FIG. 1D. Various arrangement other than the above can be employed as long as the sensor members 511a and the sensor members 511b are arranged to overlap with the adhesive region 504 and the vicinity thereof. Note that the sensor member 511a and the sensor member 511b are preferably in contact with part of the exterior body 509, in which case a pressure due to deformation is easily applied.

As described above, the present invention can provide a highly sensitive sensor by provision of a sensor member including a piezoelectric element for a secondary battery.

A crystal or a ferroelectric ceramics material can be used as a piezoelectric material contained in the piezoelectric element, and polyvinylidene fluoride (PVDF), polylactic acid (PLA), or the like may be used. For example, polylactic acid (PLA) is a crystalline helical chiral polymer and can have piezoelectricity when formed into a uniaxially stretched film. In the case of a uniaxially stretched film, a coaxial linear structure is preferable.

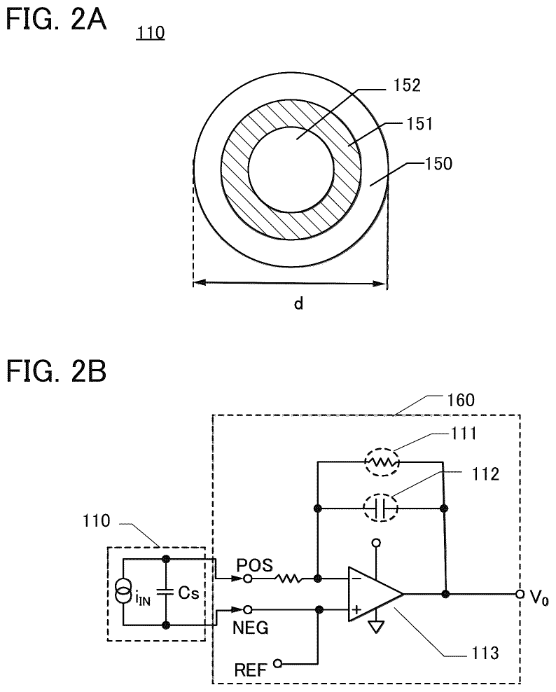

In the case where the string-like piezoelectric element has a coaxial linear structure, as illustrated in FIG. 2A, a piezoelectric fiber 151 is preferably included between a first conductive fiber 150 and a second conductive fiber 152. The string-like piezoelectric element is referred to as a piezoelectric braid. A diameter d of the piezoelectric braid is greater than or equal to 0.1 mm and less than or equal to 0.8 mm, preferably greater than or equal to 0.3 mm and less than or equal to 0.5 mm. Such a string-like sensor member is preferable because it is likely to follow expansion or the like of the exterior body 509.

As the piezoelectric fiber 151, a braid containing a fiber of polyactic acid (PLA) (this is referred to as a piezoelectric braid in some cases) may be used.

FIG. 2B illustrates a detection circuit 160 of the case where a string-like sensor member is used. Although FIG. 2B illustrates the detection circuit 160 of the case where a piezoelectric braid 110 is used as a sensor member as an example, any other sensor member may be used.

The detection circuit 160 is a circuit electrically connected to the sensor member, and includes at least a resistor 111, a capacitor 112, and an operational amplifier 113. Note that the resistor 111 can be omitted in the detection circuit 160.

The piezoelectric braid 110 includes a capacitor Cs and a current source iᵢₙ. Outputs from the piezoelectric braid 110 are denoted by POS and NEG.

Expansion or the like of the exterior body 509 applies a pressure, specifically a tension, to the piezoelectric braid 110. Accordingly, polarization charge is induced in the piezoelectric braid 110, and the generated charge is retained in the capacitor 112 of the detection circuit 160.

The operational amplifier 113 of the detection circuit 160 operates as an inverting amplifier, and can output a voltage Vo such that POS and REF have the same potential. That is, the detection circuit 160 can obtain the voltage Vo proportional to the retained charge. The voltage Vo output from the detection circuit 160 as an electric signal is input to a protection circuit or the like.

In the case where the resistor 111 is provided in the detection circuit 160, the resistance value is preferably set high.

In the above manner, a secondary battery including a sensor member with high detection sensitivity and a detection circuit electrically connected to the sensor member can be provided, and a storage battery system including the secondary battery can be provided.

This embodiment can be used in appropriate combination with the other embodiments.

### Embodiment 2

This embodiment describes an example where a test related to expansion of a secondary battery (also referred to as an expansion test) is performed and a learning model is constructed on the basis of data obtained from the test. Since expansion of a secondary battery degrades safety, the expansion state needs to be grasped at high accuracy. The expansion or the like is caused by, for example, gas generation due to a chemical reaction of an electrolyte solution or the like, and deformation in accordance with the expansion or the like partly depends on a member of the secondary battery. In view of this, as described in this embodiment, a secondary battery that stores data obtained from the expansion test (including data derived from the member of the secondary battery, such as an exterior body) as an estimated value enables highly accurate grasp of deformation of the secondary battery due to expansion or the like as compared with conventional secondary batteries. Furthermore, the secondary battery that records data obtained from the expansion test preferably includes a unit providing information based on the deformation. Note that the expansion test may include a contraction process, in which case the results of the expansion test can be acquired as data.

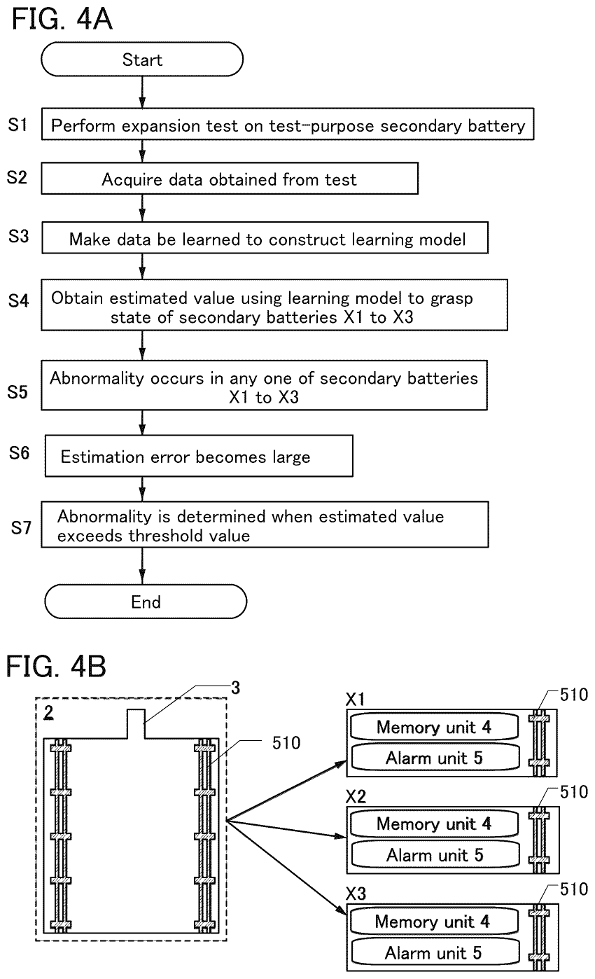

FIG. 4 shows a procedure of constructing the learning model. The construction procedure is roughly divided into data acquisition, data pretreatment, model formation, and model evaluation, and the data acquisition is described first.

### <Step S1: Conduction of Test>

First, in Step S1 in FIG. 4A, an expansion test is performed on a laminated-cell secondary battery (also referred to as test-purpose secondary battery) that is used as a reference. As a test-purpose secondary battery 2, a battery provided with the sensor member 510 and the like illustrated in FIG. 1 or the like is prepared. Examples of the expansion test include a method where a gas is intentionally introduced to the test-purpose secondary battery 2 to collect a lot of accurate information on expansion of the exterior body, as shown in FIG. 4B. Thus, the exterior body of the test-purpose secondary battery 2 may include a gas inlet 3. For the gas used in the expansion test, a material whose composition or the like is known is preferably used.

In the expansion test, a gas-filling portion may be provided in part of the exterior body of the test-purpose secondary battery in order to emphasize the expansion state. The gas-filling portion includes a bag-like portion, and the bag-like portion can be formed utilizing part of the exterior body.

### <Step S2: Data Acquisition>

In Step S2 in FIG. 4A, data obtained by the expansion test is acquired. A variety of data is preferably acquired as the data. For example, data a on an environment of the expansion test, such as temperature, is acquired. For example, data b on introduced gases in the expansion test, such as gas flows or the total gas amount, is acquired. For example, data c on the expansion amount of the test-purpose secondary battery 2 (including data on a state change with an appearance change derived from the member of the secondary battery, such as the exterior body) is acquired. The data c includes data of the case where a crack is generated in the exterior body. Any one or all of the data a to the data c or an appropriate combination thereof are dealt as data obtained from the test. The number of pieces of data is preferably large.

The learning model is preferably formed using the expansion amount of at least the data c, among the data a to the data c. This is because the storage battery system can estimate the deterioration amount of the secondary battery from the expansion amount.

The data obtained from the test can be obtained from one expansion test. In the case where the expansion test is conducted twice or more, data including data of the second and subsequent expansion tests can be acquired. Alternatively, when a plurality of test-purpose secondary batteries are prepared, data obtained from the tests on the plurality of test-purpose secondary batteries can be acquired. It is preferable to increase the number of the expansion tests or to use a plurality of test-purpose secondary batteries, in which case collected data are added and the data accuracy can be increased.

### <Step S3: Data Pretreatment and Model Formation>

Next, as the data pretreatment, linear interpolation, normalization, and the like are performed on the data. In this manner, highly accurate data is preferably prepared. The data prepared in Step S3 in FIG. 4A is input to form the learning model. Arithmetic processing of formation, i.e., construction of the learning model may be executed by the test-purpose secondary battery 2 or may be executed by a server device. The server device preferably has a function of a cloud server, an AI (Artificial Intelligence) server, a GPU (Graphics Processing Unit) server, or the like. The server device preferably includes an algorithm with a neural network. Other than the GPU, a CPU (Central Processing Unit) is preferably included. The GPU or the CPU enables high-speed arithmetic processing.

In the case where the server device performs arithmetic operation, the arithmetic results can be transmitted from a secondary battery X1 to a secondary battery X3 by wireless communication, as shown in FIG. 4B. The secondary battery X1 to the secondary battery X3 each preferably include a memory unit 4 storing the learning model.

In the case where the server device performs arithmetic operation, the arithmetic results may be transmitted to the test-purpose secondary battery 2 by wireless communication. The test-purpose secondary battery 2 preferably includes a memory unit or the like storing the learning model.

In this embodiment, to form a learning model, an optimum weight and bias are set for each node at which neurons are connected. It is preferable that Chainer be used as a framework and full-connected neural network processing be performed on the basis of the MNIST official source. Note that a program of the software executing an inference program for the neural network processing can be described in a variety of programing languages such as Python, Go, Perl, Ruby, Prolog, Visual Basic, C, C++, Swift, Java (registered trademark), and NET. Moreover, an application may be made using a framework such as Chainer (it can be used with Python), Caffe (it can be used with Python or C++), and TensorFlow (it can be used with C, C++, or Python). Note that Adam is used as an optimizer that performs optimization. At least one or more selected from the data a to the data c are used as learning data and the total gas amount is made to be learn as a correct label.

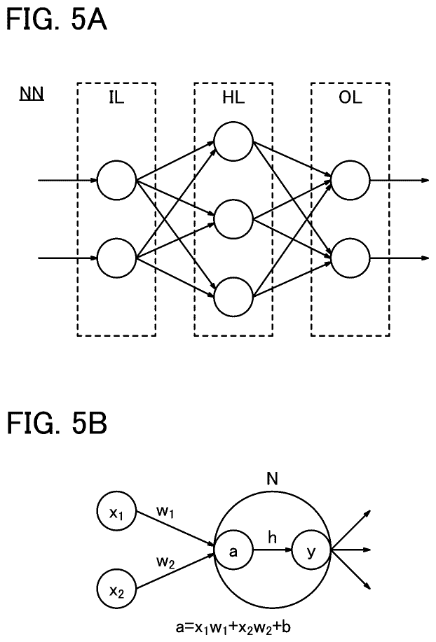

Here, an example of arithmetic operation in neural network processing NN is described with reference to FIG. 5A and FIG. 5B.

As illustrated in FIG. 5A, the neural network processing NN can be composed of an input layer IL, an output layer OL, and a middle layer (including a hidden layer) HL. The input layer IL, the output layer OL, and the middle layer HL each include one or more neurons (units). Note that the middle layer HL may be composed of one layer or two or more layers. Neural network processing including two or more middle layers HL can also be referred to as DNN (deep neural network), and learning using deep neural network processing can also be referred to as deep learning.

Prepared data is input to each neuron of the input layer IL, output signals of neurons in the previous layer or the subsequent layer are input to each neuron of the middle layer HL, and output signals of neurons in the previous layer are input to each neuron of the output layer OL. Note that each neuron may be connected to all the neurons in the previous and subsequent layers (full connection), or may be connected to some of the neurons.

FIG. 5B illustrates an example of an arithmetic operation with the neurons. Here, a neuron N and two neurons in the previous layer which output signals to the neuron N are illustrated. An output x₁ of a neuron in the previous layer and an output x₂ of a neuron in the previous layer are input to the neuron N. Then, in the neuron N, a total sum x₁w₁+x₂w₂ of the product of the output x₁ and a weight w₁ (x₁w₁) and the product of the output x₂ and a weight w₂ (x₂w₂) is calculated, and then a bias b is added as necessary, so that a value a=x₁w₁+x₂w₂+b is obtained. Subsequently, the value a is converted with an activation function h, and an output signal y=h(a) is output from the neuron N.

In this manner, the arithmetic operation with the neurons includes the arithmetic operation that sums the products of the input data and the weights, that is, a product-sum operation. The product-sum operation can be performed by the server device. In addition, signal conversion with the activation function h can be performed by a hierarchical output circuit. In other words, the operation of the middle layer HL or the output layer OL can be performed by an arithmetic circuit.

The cell array included in the product-sum operation circuit is composed of a plurality of memory cells arranged in a matrix.

The memory cells each have a function of storing first data. The first data is data corresponding to the weight between the neurons of the neural network processing. In addition, the memory cells each have a function of multiplying the first data by second data that is input from the outside of the cell array. That is, the memory cells each have a function of a memory circuit and a function of a multiplier circuit.

Note that in the case where the first data is analog data, the memory cells each have a function of an analog memory. Alternatively, in the case where the first data is multilevel data, the memory cells each have a function of a multilevel memory.

The multiplication results in the memory cells in the same column are summed up. Thus, the product-sum operation of the first data and the second data is performed. Then, the results of the operation in the cell array are output to the hierarchical output circuit as third data.

The hierarchical output circuit has a function of converting the third data output from the cell array in accordance with a predetermined activation function. An analog signal or a multilevel digital signal output from the hierarchical output circuit corresponds to the output data of the middle layer or the output layer in the neural network processing NN.

As the activation function, for example, a sigmoid function, a tan h function, a softmax function, a ReLU function, a threshold function, or the like can be used. The signal converted by the hierarchical output circuit is output as analog data or multilevel (binary, ternary, or higher-level) digital data.

In this manner, one of the arithmetic operations of the middle layer HL and the output layer OL in the neural network processing NN can be performed by the arithmetic circuit. Note that the product-sum operation circuit and the hierarchical output circuit included in the arithmetic circuit are denoted by the product-sum operation circuit and the hierarchical output circuit, respectively. In addition, analog data or multilevel digital data is output from the arithmetic circuit.

Analog data or multilevel digital data output from a first arithmetic circuit is supplied to a second arithmetic circuit as the second data. Then, the second arithmetic circuit performs an arithmetic operation using the first data stored in the memory cells and the second data input from the first arithmetic circuit. Thus, arithmetic operation of neural network processing composed of a plurality of layers can be performed.

Data can be made to be learn using the arithmetic operation of the neural network processing described with reference to FIG. 5, so that the learning model can be constructed. Then, the constructed learning model may be evaluated; for example, the accuracy of the model can be verified by Hold-out.

### <Step S4>

In Step S4 in FIG. 4A, estimated values of the secondary battery x1 to the secondary battery x3 are obtained to grasp the states (including the deterioration states) of the secondary battery x1 to the secondary battery x3 using the above learning model.

Note that the amount of reduction in lithium amount correlates to the amount of decrease in battery capacity, and thus the deterioration factor can be estimated on the basis of data on the amount of reduction in lithium amount. As one of the deterioration factors, oxidation composition of an electrolyte solution which occurs around the end of charging is included. As another one of the deterioration factors, reduction composition of an electrolyte solution around the end of charging is included. Input of data obtained by classifying these deterioration factors enables estimation of the degree of deterioration on the positive electrode side or the degree of deterioration on the negative electrode side.

### <Step S5>

In Step S5 in FIG. 4A, abnormality is assumed to occur in any one of the secondary battery X1 to the secondary battery X3 that are being used.

### <Step S6>

The any one of the secondary battery X1 to the secondary battery X3 in which abnormality occurs outputs an error between the measured value and the estimated value obtained from the expansion test (estimation error). Then, when the estimation error is large in Step S6 in FIG. 4A, occurrence of abnormality is determined. Remarkable abnormality includes a rapidly expanded state.

### <Step S7>

When the estimation error in S6 exceeds the threshold value, the storage battery system determines occurrence of abnormality in Step S7 in FIG. 4A. The secondary battery X1 to the secondary battery X3 each preferably include an alarm unit 5 for providing information on abnormality or the like. The secondary battery X1 to the secondary battery X3 may each include a unit that regularly provides information on the state of the secondary battery other than abnormality.

Note that in order to distinguish noise occurrence and anomaly occurrence, the threshold value of the estimation error is determined in advance.

If abnormality occurs, the abnormality can be detected through Step S5 to Step S7.

In the above manner, the storage battery system of this embodiment can detect abnormality in a secondary battery by performing an expansion test on a test-purpose secondary battery and constructing a learning model on the basis of the data.

This embodiment can be used in appropriate combination with the other embodiments.

### Embodiment 3

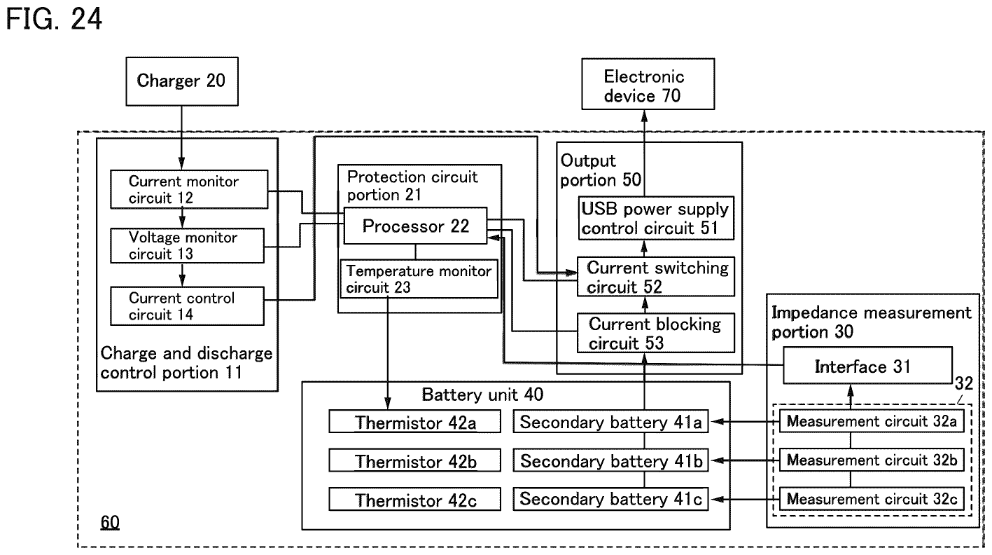

This embodiment describes an example of a storage battery system including a secondary battery including a sensor member illustrated in FIG. 1, FIG. 2, and the like with reference to FIG. 24. Note that FIG. 24 illustrates circuits and the like provided for other than construction of the learning model.

A storage battery system 60 has a function of receiving electric power supply from a charger 20 such as an AC adapter. The charger 20 can supply a current to a charge and discharge control portion 11.

The charge and discharge control portion 11 includes a current monitor circuit 12, a voltage monitor circuit 13, a current control circuit 14, and the like. The current monitor circuit 12 and the voltage monitor circuit 13 can each use an IC (integrated circuit), and can use a MOSFET (metal-oxide-semiconductor field-effect transistor) as a switching element. The MOSFET has a switch control function, and a current path can be blocked with the switch control function. The current monitor circuit 12 or the voltage monitor circuit 13 has a function of turning off the storage battery system 60 or a secondary battery in the case where a voltage out of the usage range of the secondary battery is applied, for example, in the case where a user connects the positive electrode and the negative electrode incorrectly. The charge and discharge control portion 11 may include a battery charge control circuit. With the battery charge control circuit, a constant current charging can be switched to a constant voltage charging when a voltage reaches a predetermined value, whereby an efficient charging environment can be provided. In addition, the charge and discharge control portion 11 may include an overcurrent detection circuit. The overcurrent detection circuit can protect the circuits or the secondary battery from a large current or an abnormal current.

The storage battery system 60 includes a protection circuit portion 21. The protection circuit portion 21 includes a processor 22 and a temperature monitor circuit 23. The processor 22 can receive a signal from the current monitor circuit 12 and the voltage monitor circuit 13. The temperature monitor circuit 23 includes a thermistor or the like and has a function of stopping charging and discharging in accordance with temperature. Charging and discharging with a rapid temperature increase or at an extremely low temperature, for example, not only shortens the lifetime of the secondary battery but also causes a dangerous state such as thermal runaway in some cases. The temperature monitor circuit 23 can inhibit the dangerous state such as thermal runaway. A voltage monitor circuit may be included as the protection circuit portion 21, and the voltage monitor circuit can have a function of an overcharge and/or overdischarge protection circuit. The overcharge and/or overdischarge protection circuit can perform control of power supply blocking in overdischarging or the like as well as protection of a secondary battery in a normal state, so that the storage battery system 60 or the secondary battery can be stopped safely.

An impedance measurement portion 30 includes an interface 31, and the interface 31 also supplies a signal to the processor 22. The impedance measurement portion 30 further includes a measurement circuit 32. A plurality of measurement circuits 32 are preferably provided in accordance with the number of the secondary batteries. In FIG. 24, a first measurement circuit 32a to a third measurement circuit 32c are included. The measurement circuit 32 can output a signal to the interface 31, and the signal is input to the processor 22 through the interface 31.

The storage battery system 60 includes a battery unit 40. The battery unit 40 includes a plurality of secondary batteries. FIG. 24 illustrates an example where three secondary batteries, which are a secondary battery 41a to a secondary battery 41c, are arranged in parallel. The secondary battery 41a to the secondary battery 41c each preferably include a sensor member as illustrated in FIG. 1, FIG. 2, or the like. The secondary batteries are provided with a thermistor 42a to a thermistor 42c, and the thermistors are controlled by the temperature monitor circuit 23. That is, the temperature monitor circuit 23 can monitor the temperature environment of the battery unit 40.

The storage battery system 60 includes an output portion 50. The output portion 50 includes a USB power supply control circuit 51, and additionally includes a current switching circuit 52, a current blocking circuit 53, and the like. The USB power supply control circuit 51 can be formed using an IC or the like. The USB power supply control circuit 51 has a function of supplying USB power stably and monitoring the connection state in order to prevent malfunction on a connection device side. The current switching circuit 52 can be formed using an IC, a MOSFET, and the like and is supplied with a signal from the current control circuit 14. Electric power is supplied from an external power source to the current switching circuit 52 in the case where there is an external power source input, and electric power is supplied from the secondary battery to the current switching circuit 52 in the case where there is no external power source input. Furthermore, electric power is supplied from the current switching circuit 52 to the USB power supply control circuit 51. The current blocking circuit 53 can be formed using a microcontroller or a MOSFET (e.g., N-type MOSFET). The current blocking circuit 53 has a function of blocking power supply to protect a secondary battery at the time of overcharge detection, overdischarge detection, overcurrent detection, or abnormal temperature. The current blocking circuit 53 has at least a switching function, and a MOSFET (e.g., N-type MOSFET) can be used as the switch. The current blocking circuit 53 can prevent recharging after overdischarging is detected.

The output portion 50 has a function of supplying a signal to an electronic device 70. The electronic device 70 is preferably conformable to USB power feeding. Examples of the electronic device 70 include a smartphone, a tablet electronic device, a lighting device, and a blower.

Furthermore, the storage battery system 60 may have a function of constructing the learning model of the above embodiment, specifically, may include a circuit or the like constructing the learning model of the above embodiment.

Furthermore, the storage battery system 60 may have a function of storing the learning model of the above embodiment, specifically, may include a circuit or the like storing the learning model of the above embodiment.

Furthermore, the storage battery system 60 may have a function of providing information with the use of the learning model of the above embodiment as an estimated value, specifically, may include a circuit or the like providing information with the use of the learning model of the above embodiment as an estimated value.

This embodiment can be used in appropriate combination with the other embodiments.

### Embodiment 4

In this embodiment, structures and the like of a secondary battery of one embodiment of the present invention are described.

### [Positive Electrode]

A positive electrode used for one embodiment of the present invention is described. For example, the positive electrode 503 described in Embodiment 1 includes a positive electrode active material layer and a positive electrode current collector. The positive electrode active material layer includes a positive electrode active material, and further includes a conductive material and a binder.

### [Positive Electrode Active Material]

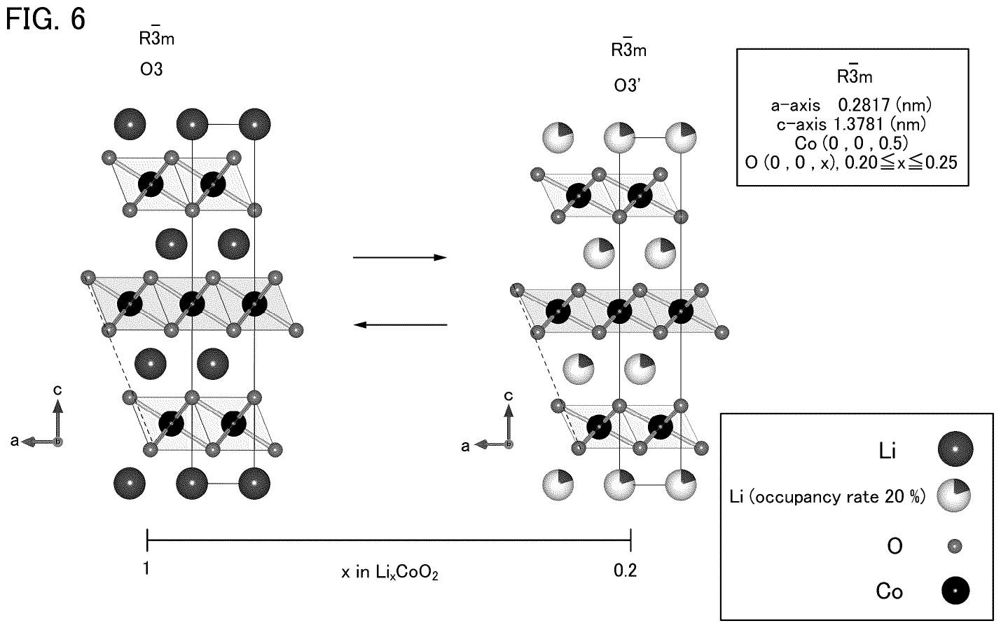

The positive electrode active material will be described below. FIG. 6 illustrates the crystal structures of a positive electrode active material of one embodiment of the present invention before and after charging and discharging. Lithium cobalt oxide containing lithium, cobalt as a transition metal M, and oxygen is described as an example of the positive electrode active material.

The lithium cobalt oxide preferably contains an additive element. As the additive element, it is preferable to use one or two or more selected from nickel, cobalt, magnesium, calcium, chlorine, fluorine, aluminum, manganese, titanium, zirconium, yttrium, vanadium, iron, chromium, niobium, lanthanum, hafnium, zinc, silicon, sulfur, phosphorus, boron, and arsenic. For example, the lithium cobalt oxide contains magnesium or aluminum as the additive element, and fluorine is preferably added as the additive element.

The lithium cobalt oxide containing the above additive element has, as a crystal structure in FIG. 6 with a Li occupancy rate of 1, that is, with a charge depth of 0 (in a discharge state), a layered-rock-salt crystal structure belonging to the space group R-3m. In FIG. 6, the crystal structure with a Li occupancy rate of 1 is denoted by R-3m O3.

The lithium cobalt oxide containing the above additive element has, as a crystal structure of when the lithium cobalt oxide is sufficiently charged to a Li occupancy rate of 0.2, that is, a charge depth of 0.8, a trigonal crystal structure belonging to the space group R-3m. In the crystal structure with a Li occupancy rate of 0.2, the symmetry of CoO₂ layers is the same as that in O3. Thus, this crystal structure with a Li occupancy rate of 0.2 is called an O3′ type crystal structure. In FIG. 6, the crystal structure with a Li occupancy rate of 0.2 is denoted by R-3m O3′.

The O3′ type crystal structure can be regarded as a crystal structure that contains lithium between layers randomly and is similar to a CdCl₂ crystal structure. The crystal structure similar to the CdCl₂ crystal structure is close to a crystal structure of lithium nickel oxide when charged up to a charge depth of Li_{0.06}NiO₂; however, pure lithium cobalt oxide or a layered rock-salt positive electrode active material containing a large amount of cobalt is known not to have the CdCl₂ crystal structure in general.

In the unit cell of the O3′ type crystal structure, the coordinates of cobalt and oxygen can be represented by Co (0, 0, 0.5) and O (0, 0, x) within the range of 0.20≤x≤0.25. In the unit cell of the O3′ type crystal structure, the lattice constant of the a-axis is preferably 0.2797≤a≤0.2837 (nm), further preferably 0.2807≤a≤0.2827 (nm), typically a=0.2817 (nm). The lattice constant of the c-axis is preferably 1.3681≤c≤1.3881 (nm), further preferably 1.3751≤c≤1.3811 (nm), typically, c=1.3781 (nm).

As denoted by dotted lines in FIG. 6, the CoO₂ layers hardly shift between the R-3m O3 in a discharged state and the O3′ type crystal structure.

The R-3m O3 in a discharged state and the O3′ type crystal structure that contain the same number of cobalt atoms have a difference in volume of 2.5% or less, more specifically 2.2% or less, typically 1.8%, i.e., the difference in volume is extremely small.

As described above, in the positive electrode active material 100 of one embodiment of the present invention, a change in the crystal structure caused when x in LixCoO₂ is small (for example, when 0.1<x≤0.24), that is, when a large amount of lithium is extracted, is smaller than that in a conventional positive electrode active material. In addition, a change in volume is smaller in the positive electrode active material 100 of one embodiment of the present invention than in a conventional positive electrode active material, in the case where the positive electrode active materials having the same number of cobalt atoms are compared. Thus, the crystal structure of the positive electrode active material 100 is less likely to be broken even when charging that makes x be 0.24 or less and discharging are repeated, so that a decrease in charge and discharge capacity of the positive electrode active material 100 in charge and discharge cycles is inhibited. Furthermore, the positive electrode active material 100 can stably use a larger amount of lithium than a conventional positive electrode active material, and thus has a large discharge capacity per weight and per volume and enables fabrication of a secondary battery with a large discharge capacity per weight and per volume.

Note that the positive electrode active material 100 is confirmed to have the O3′ type crystal structure in some cases when x in LixCoO₂ satisfies 0.1<x≤0.24, and is assumed to have the O3′ type crystal structure even when x is greater than 0.24 and less than or equal to 0.27.

The crystal structure is influenced by not only x in LixCoO₂ but also the number of charge and discharge cycles, charge and discharge current, temperature, an electrolyte, or the like. Hence, when x in LixCoO₂ of the positive electrode active material 100 satisfies 0.1<x≤0.24, the positive electrode active material 100 does not need to entirely have the O3′ type crystal structure. When x in LixCoO₂ satisfies 0.1<x≤0.24, the positive electrode active material 100 may have another crystal structure or may be partly amorphous.

In order to make x in LixCoO₂ small, charging is performed at a high charge voltage, and the state where x in LixCoO₂ is small can be referred to as a state where charging is performed at a high charge voltage. For example, when CC charging/CV charging (constant voltage charging/constant current charging) are performed at 25° C. at a voltage of 4.6 V or higher with reference to a potential of a lithium metal, not the O3′ type crystal structure but the H1-3 type crystal structure appears in a conventional positive electrode active material. The charge voltage of 4.6 V or higher with reference to the potential of a lithium metal can be referred as a high charge voltage. That is, the positive electrode active material 100 of one embodiment of the present invention can have the O3′ type crystal structure even when charged at 25° C. at a high voltage of 4.6 or higher, for example. In this specification and the like, unless otherwise specified, a charge voltage is shown with reference to the potential of a lithium metal.

As described above, the crystal structure is influenced by the number of charge and discharge cycles, a charge current and a discharge current, an electrolyte, and the like, so that the positive electrode active material 100 of one embodiment of the present invention sometimes has the O3′ type crystal structure even at a lower charge voltage, e.g., a charge voltage of higher than or equal to 4.5 V and lower than 4.6 V at 25° C.

Note that in the case where graphite is used as a negative electrode active material in a secondary battery, for example, the above-described voltage decreases by the potential of graphite. The potential of graphite is approximately 0.05 V to 0.2 V with reference to the potential of a lithium metal. Thus, in the case of a secondary battery using graphite as a negative electrode active material, the charge voltage corresponds to a voltage obtained by subtracting the potential of the graphite from the above-described charge voltage.

Examples of the positive electrode active material other than the lithium cobalt oxide include a composite oxide with an olivine crystal structure, a composite oxide with a layered rock-salt crystal structure, and a composite oxide with a spinel crystal structure. For example, a compound such as LiFePO₄, LiFeO₂, LiNiO₂, LiMn₂O₄, V₂O₅, Cr₂O₅, or MnO₂ can be given.

As another positive electrode active material, it is preferable to mix lithium nickel oxide (LiNiO₂ or LiNi₁₋ₓMₓO₂ (0<x<1) (M=Co, Al, or the like)) with a lithium-containing material that has a spinel crystal structure and contains manganese, such as LiMn₂O₄. This composition can improve the characteristics of the secondary battery.

Another example of the positive electrode active material is a lithium-manganese composite oxide that can be represented by a composition formula LiₐMn_{b}M_{c}O_{d}. Here, the element M is preferably silicon, phosphorus, or a metal element other than lithium and manganese, further preferably nickel. In the case where the whole particles of a lithium-manganese composite oxide are measured, it is preferable to satisfy the following at the time of discharging: 0<a/(b+c)<2; c>0; and 0.26<(b+c)/d<0.5.

Note that the proportions of metals, silicon, phosphorus, and other elements in the whole particles of a lithium-manganese composite oxide can be measured with, for example, an ICP-MS (inductively coupled plasma mass spectrometer). The proportion of oxygen in the whole particles of a lithium-manganese composite oxide can be measured by, for example, EDX (energy dispersive X-ray spectroscopy). Alternatively, the proportion of oxygen can be measured by ICPMS combined with fusion gas analysis and valence evaluation of XAFS (X-ray absorption fine structure) analysis. Note that the lithium manganese composite oxide refers to an oxide containing at least lithium and manganese, and may contain an additive element.

### [Conductive Material]

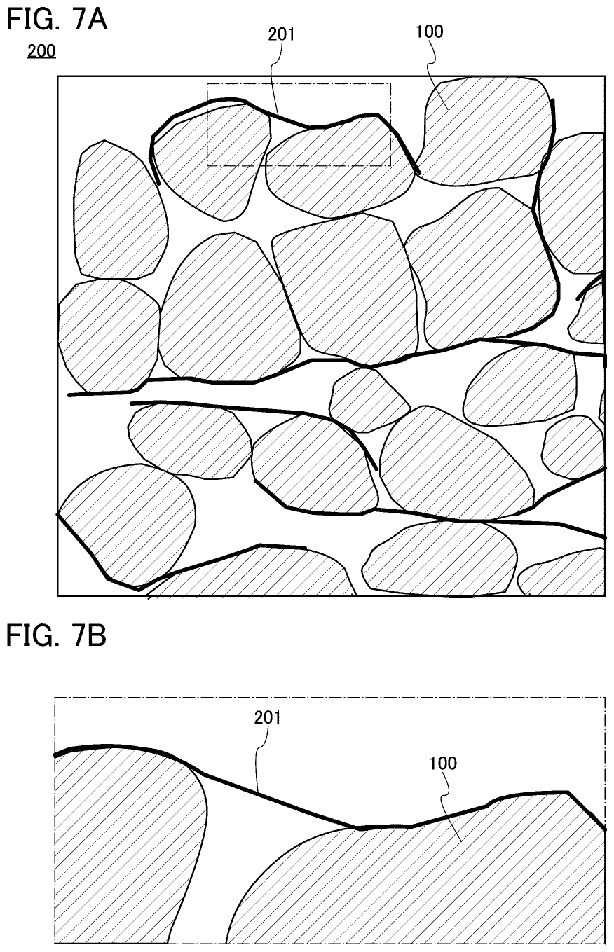

A conductive material is described. FIG. 7A illustrates a positive electrode active material layer 200. The positive electrode active material layer 200 contains the above-described positive electrode active material 100 and a conductive material 201. The positive electrode active material 100 has a particulate shape, but is not limited to having this shape. Graphene or a graphene compound is used as the conductive material 201. The positive electrode active material layer 200 may include a binder, but the binder is not illustrated in FIG. 7A.

Graphene includes multilayer graphene and multi graphene. The graphene compound includes graphene oxide, multilayer graphene oxide, multi graphene oxide, reduced graphene oxide, reduced multilayer graphene oxide, reduced multi graphene oxide, graphene quantum dots, and the like.

The graphene contains carbon, has a plate-like shape, a sheet-like shape, or the like, and has a two-dimensional structure formed of a six-membered ring composed of carbon atoms. The two-dimensional structure formed of the six-membered ring composed of carbon atoms may be referred to as a carbon sheet.

A graphene compound may include a functional group.

Graphene oxide contains carbon and oxygen, has a sheet-like shape, and includes a functional group, in particular, an epoxy group, a carboxy group, or a hydroxy group.

Reduced graphene oxide contains carbon and oxygen, has a sheet-like shape, and has a two-dimensional structure formed of a six-membered ring composed of carbon atoms. In the case where reduce graphene oxide includes defects, a 7- or more-membered ring is observed. Sufficiently reduced graphene oxide may be referred to as a carbon sheet. One sheet of reduced graphene oxide or stacked sheets of reduced graphene oxide may be used. Reduced graphene oxide preferably includes a portion where the carbon concentration is higher than 80 atomic % and the oxygen concentration is higher than or equal to 2 atomic % and lower than or equal to 15 atomic %. With such a carbon concentration and such an oxygen concentration, reduced graphene oxide can function as a conductive material with high conductivity even with a small amount. In addition, the intensity ratio G/D of a G band to a D band of the Raman spectrum of reduced graphene oxide is preferably 1 or more. Reduced graphene oxide with such an intensity ratio can function as a conductive material with high conductivity even with a small amount.

Graphene or a graphene compound may have a bent shape. Graphene or a graphene compound may be rounded like a carbon nanofiber.

Graphene and a graphene compound may have excellent electrical characteristics of high conductivity and excellent physical properties of high flexibility and high mechanical strength. Graphene or a graphene compound can have a sheet-like shape. Graphene or a graphene compound can have a curved surface, thereby enabling wide-area contact and low-resistant surface contact. Furthermore, graphene or a graphene compound has extremely high conductivity even with a small thickness, and thus can form a conductive path in an active material layer even with a small amount. Hence, the use of graphene or a graphene compound as a conductive material can increase the area where an active material and the conductive material are in contact with each other. Graphene or a graphene compound preferably covers 80% or more of the area of an active material. Note that graphene or a graphene compound has high flexibility, and thus can cling to at least part of an active material. In addition, graphene or a graphene compound is preferably positioned to overlap with at least part of an active material. In the case where graphene or a graphene compound is extremely thin, the shape of part of the graphene or the graphene compound is along the shape of an active material in some cases. The shape of an active material indicates, for example, unevenness of a single active material or unevenness formed by a plurality of active materials. Graphene or a graphene compound preferably surrounds at least part of an active material. Graphene or a graphene compound may have a hole. The hole is observed as a poly-membered ring.

When an active material with a median diameter (D50) (e.g., 1 μm or less) is used, the specific surface area of the active material becomes large and thus more conductive paths for the active materials are needed. In such a case, it is preferable to use graphene or a graphene compound that can efficiently form a conductive path even with a small amount be used.

It is particularly effective to use graphene or a graphene compound, which has the above-described properties, as the conductive material 201 of a secondary battery that needs to be rapidly charged and discharged. For example, a mobile electronic device or the like is required to have fast charge characteristics in some cases. Fast charging and discharging may also be referred to as charging and discharging at a high rate, for example, at a rate of 1 C, 2 C, or 5 C or more.

FIG. 7B is an enlarged view of a region surrounded by a dashed dotted line in FIG. 7A. The sheet-like conductive material 201 positioned along the unevenness of the positive electrode active material 100 is included. When placed in such a manner, the conductive material 201 can be substantially uniformly dispersed in the positive electrode active material layer 200. Although the conductive material 201 is schematically shown by a thick line in FIG. 7B, graphene or a graphene compound is actually a thin film having a thickness corresponding to the thickness of a single layer or a multilayer of carbon molecules. The conductive material 201 is formed to partly coat the plurality of particles of the positive electrode active material 100 or to adhere to the surfaces of the plurality of particles of the positive electrode active material 100. Thus, the conductive material 201 includes a region being in surface contact with the positive electrode active material 100.

Here, a plurality of sheets of graphene or the plurality of graphene compounds can be bonded to each other to form a net-like graphene compound sheet (hereinafter, referred to as a graphene compound net or a graphene net). In the case where a graphene net covers the active material, the graphene net can function as a binder for bonding the active materials. Accordingly, the amount of the binder can be reduced, or the binder does not have to be used, which can increase the proportion of the active material in the electrode volume or the electrode weight. That is, the charge and discharge capacity of the secondary battery can be increased.

The positive electrode is preferably formed in the following manner: graphene oxide is used as a graphene compound, at least the graphene oxide and the positive electrode active material 100 are mixed to form a layer to be the positive electrode active material layer 200, and then the graphene oxide is reduced. That is, the formed active material layer preferably contains reduced graphene oxide. When graphene oxide with extremely high dispersibility in a polar solvent is used as the graphene compound, the graphene oxide can be substantially uniformly dispersed in the positive electrode active material layer 200. The solvent is removed by volatilization or evaporation from a dispersion medium containing the uniformly dispersed graphene oxide; hence, the sheets of the reduced graphene oxide remaining in the positive electrode active material layer 200 partly overlap and make surface contact with each other, thereby forming a three-dimensional conductive path. Note that graphene oxide may be reduced by heat treatment or with use of a reducing agent, for example.

Graphene or a graphene compound is capable of making low-resistance surface contact, and thus can improve the electrical conduction with the positive electrode active material 100 with a small amount as compared with a particulate conductive material. Accordingly, the proportion of the positive electrode active material in the positive electrode active material layer 200 can be increased. Thus, discharge capacity of the secondary battery can be increased.

A graphene compound may be used as a conductive material formed with a splay dry apparatus to cover the entire surface of the active material. It is also possible to form a coating film of a graphene compound with the use of a spray dry apparatus so that a conductive path between the active materials is formed by the graphene compound of the coating film.

A material used in formation of the graphene compound may be mixed with the graphene compound to be used for the positive electrode active material layer 200. For example, particles used as a catalyst in formation of the graphene compound may be mixed with the graphene compound. As an example of the catalyst in formation of the graphene compound, particles containing silicon oxide (SiO₂ or SiOₓ (x<2)), aluminum oxide, iron, nickel, ruthenium, iridium, platinum, copper, germanium, or the like can be given. The median diameter (D50) of the particles is preferably less than or equal to 1 μm, further preferably less than or equal to 100 nm.

### [Binder]

A binder is described. A rubber material is preferably used for the binder. As the rubber material, styrene-butadiene rubber (SBR), styrene-isoprene-styrene rubber, acrylonitrile-butadiene rubber, butadiene rubber, ethylene-propylene-diene copolymer, or the like is preferable, for example. Alternatively, fluororubber can be used as the binder.

As the binder, a water-soluble polymer is preferably used. As the water-soluble polymers, a polysaccharide or the like can be used, for example. As the polysaccharide, a cellulose derivative such as carboxymethyl cellulose (CMC), methyl cellulose, ethyl cellulose, hydroxypropyl cellulose, diacetyl cellulose, or regenerated cellulose, starch, or the like can be used. It is further preferable that such water-soluble polymers be used in combination with any of the above-described rubber materials.

Alternatively, as the binder, it is preferable to use a material such as polystyrene, poly(methyl acrylate), poly(methyl methacrylate) (PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, polyvinylidene fluoride (PVDF), polyacrylonitrile (PAN), ethylene-propylene-diene polymer, polyvinyl acetate, or nitrocellulose.

A plurality of the above-described materials may be used in combination for the binder.

For example, a material having a significant viscosity modifying effect and another material may be used in combination. For example, a rubber material or the like has high adhesion or high elasticity but may have difficulty in viscosity modification when mixed in a solvent. In such a case, a rubber material or the like is preferably mixed with a material having a significant viscosity modifying effect, for example. As a material having a significant viscosity modifying effect, for instance, a water-soluble polymer is preferably used. As the water-soluble polymer having a significant viscosity modifying effect, any of the above polysaccharides can be used.

Note that a cellulose derivative such as carboxymethyl cellulose obtains a higher solubility when converted into a salt such as a sodium salt or an ammonium salt of carboxymethyl cellulose, and thus easily exerts an effect as a viscosity modifier. A high solubility can also increase the dispersibility of an active material or other components in the formation of a slurry for an electrode. In this specification, cellulose and a cellulose derivative used as a binder of an electrode include salts thereof.

A water-soluble polymer stabilizes the viscosity by being dissolved in water and allows stable dispersion of the active material or another material combined as a binder, such as styrene-butadiene rubber, in an aqueous solution. Furthermore, a water-soluble polymer is expected to be easily and stably adsorbed onto an active material surface because it has a functional group. Many cellulose derivatives, such as carboxymethyl cellulose, have a functional group such as a hydroxyl group or a carboxyl group. Because of functional groups, polymers are expected to interact with each other and cover an active material surface in a large area.

In the case where the binder that covers or is in contact with the active material surface forms a film, the film is expected to serve also as a passivation film to inhibit the decomposition of the electrolyte solution. Here, a passivation film refers to a film without electric conductivity or a film with extremely low electric conductivity, and can inhibit the decomposition of an electrolyte solution at a potential at which a battery reaction occurs when the passivation film is formed on the active material surface, for example. It is further desirable that the passivation film can conduct lithium ions while inhibiting electrical conduction.

### [Positive Electrode Current Collector]

A positive electrode current collector is described. A material with high conductivity can be used for the positive electrode current collector. Examples of the material with high conductivity include metals such as stainless steel, gold, platinum, aluminum, and titanium, and alloys thereof. It is preferable that a material used for the positive electrode current collector not be dissolved at the potential of the positive electrode. It is also possible to use, for the positive electrode current collector, an aluminum alloy to which an element that improves heat resistance, such as silicon, titanium, neodymium, scandium, or molybdenum, is added. The positive electrode current collector may be formed using a metal element that forms silicide by reacting with silicon. Examples of the metal element that forms silicide by reacting with silicon include zirconium, titanium, hafnium, vanadium, niobium, tantalum, chromium, molybdenum, tungsten, cobalt, and nickel. The positive electrode current collector can have a foil-like shape, a plate-like shape, a sheet-like shape, a net-like shape, a punching-metal shape, an expanded-metal shape, or the like as appropriate. The positive electrode current collector having a thickness greater than or equal to 5 μm and less than or equal to 30 μm is preferably used.

### [Negative Electrode]

A negative electrode used in one embodiment of the present invention is described. For example, the negative electrode 506 described in Embodiment 1 includes a negative electrode active material layer and a negative electrode current collector, and further includes a conductive material and a binder.

### [Negative Electrode Active Material]

A negative electrode active material is described. As a negative electrode active material, for example, an alloy-based material or a carbon material can be used.

Specifically, as the negative electrode active material, an element that enables charge and discharge reactions by alloying and dealloying reactions with lithium can be used. For example, a material containing at least one selected from silicon, tin, gallium, aluminum, germanium, lead, antimony, bismuth, silver, zinc, cadmium, and indium can be used. Such elements have higher charge and discharge capacity than carbon; in particular, silicon has a high theoretical capacity of 4200 mAh/g. For this reason, silicon is preferably used as the negative electrode active material. Alternatively, a compound containing any of the above elements may be used. For example, SiO, Mg₂Si, Mg₂Ge, SnO, SnO₂, Mg₂Sn, SnS₂, V₂Sn₃, FeSn₂, CoSn₂, Ni₃Sn₂, Cu₆Sn₅, Ag₃Sn, Ag₃Sb, Ni₂MnSb, CeSb₃, LaSn₃, La₃Co₂Sn₇, CoSb₃, InSb, and SbSn are given. Here, an element that enables charge and discharge reactions by alloying and dealloying reactions with lithium, a compound containing the element, and the like may be referred to as an alloy-based material.

SiO refers to silicon monoxide, for example. Note that SiO can alternatively be expressed as SiOₓ. Here, x preferably is 1 or an approximate value of 1. For example, x is preferably greater than or equal to 0.2 and less than or equal to 1.5, further preferably greater than or equal to 0.3 and less than or equal to 1.2. Alternatively, x is preferably greater than or equal to 0.2 and less than or equal to 1.2. Alternatively, x is preferably greater than or equal to 0.3 and less than or equal to 1.5.

As the carbon-based material, graphite, graphitizing carbon (soft carbon), non-graphitizing carbon (hard carbon), carbon nanotube, graphene, carbon black, or the like can be used.

Examples of graphite include artificial graphite and natural graphite. Examples of artificial graphite include mesocarbon microbeads (MCMB), coke-based artificial graphite, and pitch-based artificial graphite. Here, as artificial graphite, spherical graphite having a spherical shape can be used. For example, MCMB is preferable because it may have a spherical shape. Moreover, MCMB may be preferable because it can relatively easily have a small surface area. Examples of natural graphite include flake graphite and spherical natural graphite.

Graphite has a low potential substantially equal to that of a lithium metal (higher than or equal to 0.05 V and lower than or equal to 0.3 V vs. Li/Li⁺ when lithium ions are inserted into graphite (while a lithium-graphite intercalation compound is formed). For this reason, a lithium-ion secondary battery can have a high operating voltage. In addition, graphite is preferable because of its advantages such as a relatively high charge and discharge capacity per unit volume, relatively small volume expansion, low cost, and a higher level of safety than that of a lithium metal.

As the negative electrode active material, an oxide such as titanium dioxide (TiO₂), lithium titanium oxide (Li₄Ti₅O₁₂), a lithium-graphite intercalation compound (LiₓC₆), niobium pentoxide (Nb₂O₅), tungsten oxide (WO₂), or molybdenum oxide (MoO₂) can be used.

Alternatively, as the negative electrode active material, Li₃₋ₓMₓ—N (M=Co, Ni, or Cu) with a Li₃N structure, which is a composite nitride of lithium and a transition metal, can be used. For example, Li_{2.6}Co_{0.4}N₃ is preferable because of its high charge and discharge capacity (900 mAh/g and 1890 mAh/cm³).

A composite nitride containing lithium and a transition metal is preferably used, in which case lithium ions are contained in the negative electrode active material and thus the negative electrode active material can be used in combination with a positive electrode active material that does not contain lithium ions, such as V₂O₅ or Cr₃O₈. Note that in the case of using a material containing lithium ions as a positive electrode active material, the composite nitride containing lithium and a transition metal can be used as the negative electrode active material by extracting the lithium ions contained in the positive electrode active material in advance.

Alternatively, a material that causes a conversion reaction can be used as the negative electrode active material. For example, a transition metal oxide that does not form an alloy with lithium, such as cobalt oxide (CoO), nickel oxide (NiO), or iron oxide (FeO), may be used as the negative electrode active material. Other examples of the material that causes a conversion reaction include oxides such as Fe₂O₃, CuO, Cu₂O, RuO₂, and Cr₂O₃, sulfides such as CoS_{0.89}, NiS, and CuS, nitrides such as Zn₃N₂, Cu₃N, and Ge₃N₄, phosphides such as NiP₂, FeP₂, and CoP₃, and fluorides such as FeF₃ and BiF₃.

For the conductive material and the binder that can be included in the negative electrode active material layer, materials similar to those for the conductive material and the binder that can be included in the positive electrode active material layer can be used.

### [Negative Electrode Current Collector]

A negative electrode current collector is described. For the negative electrode current collector, a material similar to that for the positive electrode current collector can be used. Note that a material that is not alloyed with carrier ions of lithium or the like is preferably used for the negative electrode current collector.

### [Electrolyte Solution]

An electrolyte solution is described. An electrolyte solution includes a solvent and an electrolyte. As the solvent of the electrolyte solution, an aprotic organic solvent is preferably used; for example, one or more selected from ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, sultone, and the like can be used at an appropriate ratio.

The use of an ionic liquid (room temperature molten salt) that is unlikely to burn and volatize as the solvent of the electrolyte solution can prevent a secondary battery from exploding or catching fire even when the secondary battery internally shorts out or the internal temperature increases owing to overcharging or the like. An ionic liquid contains a cation and an anion, specifically, an organic cation and an anion. Examples of the organic cation used for the electrolyte solution include aliphatic onium cations such as a quaternary ammonium cation, a tertiary sulfonium cation, and a quaternary phosphonium cation, and aromatic cations such as an imidazolium cation and a pyridinium cation. Examples of the anion used for the electrolyte solution include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

As the electrolyte dissolved in the above solvent, one or more selected from lithium salts such as LiPF₆, LiClO₄, LiAsF₆, LiBF₄, LiAlCl₄, LiSCN, LiBr, LiI, Li₂SO₄, Li₂B₁₀Cl₁₀, Li₂B₁₂Cl₁₂, LiCF₃SO₃, LiC₄F₉SO₃, LiC(CF₃SO₂)₃, LiC(C₂F₅SO₂)₃, LiN(CF₃SO₂)₂, LiN(C₄F₉SO₂) (CF₃SO₂), and LiN(C₂F₅SO₂)₂ can be used at an appropriate ratio.

The electrolyte solution used for a secondary battery is preferably highly purified and contains a small number of dust particles or elements other than the constituent elements of the electrolyte solution (hereinafter, also simply referred to as “impurities”). Specifically, the weight ratio of impurities to the electrolyte solution is preferably less than or equal to 1%, further preferably less than or equal to 0.1%, still further preferably less than or equal to 0.01%.

Furthermore, an additive agent such as vinylene carbonate (VC), propane sultone (PS), tert-butylbenzene (TBB), fluoroethylene carbonate (FEC), lithium bis(oxalate)borate (LiBOB), or a dinitrile compound such as succinonitrile or adiponitrile may be added to the electrolyte solution. The concentration of the material to be added in the whole solvent is, for example, higher than or equal to 0.1 wt % and lower than or equal to 5 wt %. VC or LiBOB is particularly preferable because it facilitates formation of a favorable coating film.

An unnecessary reaction gasifies a component of the electrolyte solution and causes expansion of the secondary battery.

### [Separator]

A separator is described. Note that a separator is not provided in a secondary battery in some cases. As the separator, for example, a separator formed using paper, nonwoven fabric, glass fiber, ceramics, synthetic fiber, or the like can be used. Examples of the synthetic fiber include nylon (polyamide), vinylon (polyvinyl alcohol-based fiber), polyester, polyimide, acrylic, polyolefin, and polyurethane. Alternatively, the separator may be formed using an organic material film of polyimide, polypropylene, polyethylene, or the like.

The separator may be processed to have an envelope-like shape to wrap one of the positive electrode and the negative electrode. A separator processed to have an envelope-like shape is preferably used in a flexible secondary battery, in which case the safety is improved.

The separator may have a multilayer structure. For example, an organic material film of polypropylene, polyethylene, or the like is coated with a ceramic-based material, a fluorine-based material, a polyamide-based material, a mixture thereof, or the like, so that a multilayer structure can be formed. As the ceramic-based material, aluminum oxide particles or silicon oxide particles can be used, for example. As the fluorine-based material, PVDF or polytetrafluoroethylene can be used, for example. As the polyamide-based material, nylon or aramid (meta-based aramid or para-based aramid) can be used, for example.

A separator having a multilayer structure is preferable because it can maintain the safety of a secondary battery. Furthermore, when the separator having a multilayer structure is coated with the ceramic-based material, the oxidation resistance is improved; hence, deterioration of the separator in charging and discharging at high voltage can be inhibited and thus the reliability of the secondary battery can be improved. When the separator having a multilayer structure is coated with the fluorine-based material, the separator is easily brought into close contact with a positive electrode or a negative electrode, resulting in high output characteristics. When the separator having a multilayer structure is coated with the polyamide-based material, in particular, aramid, heat resistance is improved and thus the safety of the secondary battery can be further improved.

For example, both surfaces of an organic material film of polypropylene or the like may be coated with a mixed material of aluminum oxide and aramid to form a separator having a multilayer structure. Alternatively, a surface of an organic material film of polypropylene or the like that is in contact with the positive electrode may be coated with a mixed material of aluminum oxide and aramid, and a surface of the organic material film that is in contact with the negative electrode may be coated with the fluorine-based material to form a separator having a multilayer structure.

With the use of a separator having a multilayer structure, the safety of the secondary battery can be maintained; hence, the total thickness of the separator can be reduced and the charge and discharge capacity per volume of the secondary battery can be increased.

### [Exterior Body]

The exterior body 509 is described. For the exterior body 509, a metal material such as aluminum or a resin material can be used, for example. A film-like exterior body can also be used. As the film, for example, it is possible to use a film having a three-layer structure in which a highly flexible metal thin film of aluminum, stainless steel, copper, nickel, or the like is provided over a film formed of a material such as polyethylene, polypropylene, polycarbonate, ionomer, or polyamide, and an insulating synthetic resin film of a polyamide-based resin, a polyester-based resin, or the like is provided over the metal thin film as the outer surface of the exterior body.

The thickness of the exterior body 509 is greater than or equal to 0.1 mm and less than or equal to 0.8 mm, preferably greater than or equal to 0.1 mm and less than or equal to 0.3 mm.

This embodiment can be used in appropriate combination with the other embodiments.

### Embodiment 5

In this embodiment, methods for fabricating a positive electrode active material of one embodiment of the present invention are described.

### <<Fabrication Method 1 of Positive Electrode Active Material>>

### <Step S11>

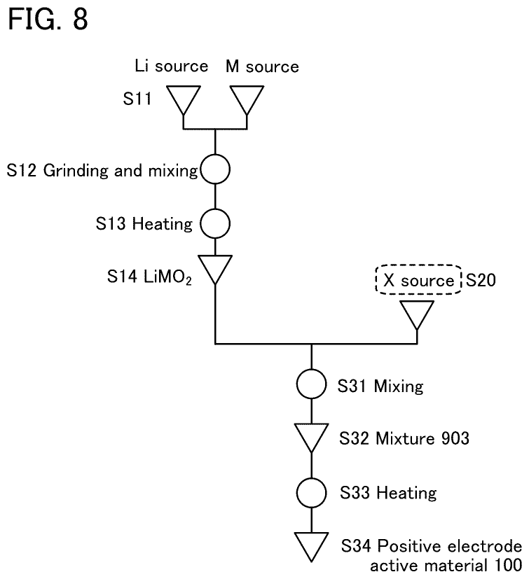

In Step S11 shown in FIG. 8, a lithium source (Li source) and a transition metal source (M source) are prepared as materials of lithium and a transition metal which are starting materials.

A compound containing lithium is preferably used as the lithium source; for example, lithium carbonate, lithium hydroxide, lithium nitrate, lithium fluoride, or the like can be used. The lithium source preferably has a high purity and is preferably a material having a purity of higher than or equal to 99.99%, for example.

The transition metal can be selected from the elements belonging to Group 4 to Group 13 of the periodic table and for example, one or more selected from manganese, cobalt, and nickel is used. As the transition metal, for example, cobalt alone; nickel alone; two metals of cobalt and manganese; two metals of cobalt and nickel; or three metals of cobalt, manganese, and nickel may be used. In the case where cobalt alone is used, the positive electrode active material to be obtained contains lithium cobalt oxide (LCO); in the case where three metals of cobalt, manganese, and nickel are used, the positive electrode active material to be obtained contains lithium nickel cobalt manganese oxide (NCM).

As the transition metal source, a compound containing the above transition metal is preferably used and for example, an oxide, a hydroxide, or the like of any of the metals given as examples of the transition metal can be used. As a cobalt source, cobalt oxide, cobalt hydroxide, or the like can be used. As a manganese source, manganese oxide, manganese hydroxide, or the like can be used. As a nickel source, nickel oxide, nickel hydroxide, or the like can be used. As an aluminum source, aluminum oxide, aluminum hydroxide, or the like can be used.

The transition metal source preferably has a high purity and is preferably a material having a purity of higher than or equal to 3N (99.9%), further preferably higher than or equal to 4N (99.99%), still further preferably higher than or equal to 4N5 (99.995%), yet still further preferably higher than or equal to 5N (99.999%), for example. Impurities of the positive electrode active material can be controlled by using the high-purity material. As a result, the capacity of a secondary battery is increased and/or the reliability of a secondary battery is increased.

Furthermore, the transition metal source preferably has high crystallinity, and preferably includes single crystal particles, for example. To evaluate the crystallinity of the transition metal source, for example, the crystallinity can be judged with a TEM (transmission electron microscope) image, an STEM (scanning transmission electron microscope) image, a HAADF-STEM (high-angle annular dark field scanning transmission electron microscope) image, an ABF-STEM (annular bright-field scan transmission electron microscope) image, or the like, or can be judged by X-ray diffraction (XRD), electron diffraction, neutron diffraction, or the like. Note that the above methods for evaluating crystallinity can also be employed to evaluate the crystallinity of other materials in addition to the transition metal source.

In the case of using two or more transition metal sources, the two or more transition metal sources are preferably prepared to have proportions (mixing ratio) such that a layered rock-salt crystal structure would be obtained.

### <Step S12>

Next, in Step S12 shown in FIG. 8, the lithium source and the transition metal source are ground and mixed to form a mixed material. The grinding and mixing can be performed by a dry process or a wet process. A wet process is preferable because it can grind a material into a smaller size. When the mixing is performed by a wet process, a solvent is prepared. As the solvent, ketone such as acetone, alcohol such as ethanol or isopropanol, ether, dioxane, acetonitrile, N-methyl-2-pyrrolidone (NMP), or the like can be used. An aprotic solvent that hardly reacts with lithium is further preferably used. In this embodiment, dehydrated acetone with a purity of higher than or equal to 99.5% is used. It is preferable that the lithium source and the transition metal source be mixed into dehydrated acetone whose moisture content is less than or equal to 10 ppm and which has a purity of higher than or equal to 99.5% in the grinding and mixing. With the use of dehydrated acetone with the above-described purity, impurities that might be mixed can be reduced.

A ball mill, a bead mill, or the like can be used as a means of the mixing and the like. When the ball mill is used, alumina balls or zirconia balls are preferably used as grinding media, for example. Zirconia balls are preferable because they release fewer impurities. When a ball mill, a bead mill, or the like is used, the peripheral speed is preferably higher than or equal to 100 mm/s and lower than or equal to 2000 mm/s in order to inhibit contamination from the media. In this embodiment, the peripheral speed is set to 838 mm/s (the rotational frequency is 400 rpm, and the diameter of the ball mill is 40 mm).

### <Step S13>

Next, the mixed material is heated in Step S13 shown in FIG. 8. The heating temperature is preferably higher than or equal to 800° C. and lower than or equal to 1100° C., further preferably higher than or equal to 900° C. and lower than or equal to 1000° C., and still further preferably approximately 950° C. An excessively low temperature might lead to insufficient decomposition and melting of the lithium source and the transition metal source. Meanwhile, an excessively high temperature might lead to a defect due to evaporation of lithium from the lithium source and/or excessive reduction of the metal used as the transition metal source, for example. The defect is, for example, an oxygen defect which could be induced by a change of trivalent cobalt into divalent cobalt due to excessive reduction, in the case where cobalt is used as the transition metal. Since the defect relates to deterioration of the positive electrode active material, the number of defects is preferably as small as possible.

The heating time is preferably longer than or equal to 1 hour and shorter than or equal to 100 hours, further preferably longer than or equal to 2 hours and shorter than or equal to 20 hours, for example.

The temperature raising rate is preferably higher than or equal to 80° C./h and lower than or equal to 250° C./h, although depending on the end-point temperature of the heating. For example, in the case of heating at 1000° C. for 10 hours, the temperature rise is preferably at 200° C./h.

The heating is preferably performed in an atmosphere with little water such as a dry-air atmosphere and for example, the dew point of the atmosphere is preferably lower than or equal to −50° C., further preferably lower than or equal to −80° C. In this embodiment, the heating is performed in an atmosphere with a dew point of −93° C. To reduce impurities that might enter the material, the concentrations of impurities such as CH₄, CO, CO₂, and H₂ in the heating atmosphere are each preferably lower than or equal to 5 ppb (parts per billion).

The heating atmosphere is preferably an oxygen-containing atmosphere. In a method, a dry air is continuously introduced into a reaction chamber. The flow rate of a dry air in this case is preferably 10 L/min. Continuously introducing oxygen into a reaction chamber to make oxygen flow therein is referred to as flowing.

In the case where the heating atmosphere is an oxygen-containing atmosphere, oxygen flowing is not necessarily performed. For example, the following method may be employed: the pressure in the reaction chamber is reduced, then the reaction chamber is filled with oxygen, and the oxygen is prevented from entering or exiting from the reaction chamber. Such a method is referred to as purging. For example, the pressure in the reaction chamber may be reduced to −970 hPa and then, the reaction chamber may be filled with oxygen until the pressure becomes 50 hPa.

Cooling after the heating can be performed by natural cooling, and the time it takes for the temperature to decrease to room temperature from a predetermined temperature is preferably longer than or equal to 10 hours and shorter than or equal to 50 hours. Note that the temperature does not necessarily need to decrease to room temperature as long as it decreases to a temperature acceptable to the next step.

The heating in this step may be performed with a rotary kiln or a roller hearth kiln. The heating with a rotary kiln can be performed while stirring is performed in either case of a sequential rotary kiln or a batch-type rotary kiln. In a rotary kiln or a roller hearth kiln, oxygen is preferably flowed.

As a crucible used at the time of the heating, an alumina crucible is preferable. An aluminum crucible is made of a material that is less likely to release impurities. In this embodiment, a crucible made of alumina with a purity of 99.9% is preferably used. The heating is preferably performed with the crucible covered with a lid. This can prevent volatilization or sublimation of a material.

The heated material is ground as needed and may be made to pass through a sieve. Before collection of the heated material, the material may be moved from the crucible to a mortar. As the mortar, an alumina mortar is suitably used. An alumina mortar is made of a material that is less likely to release impurities. Specifically, a mortar made of alumina with a purity of 90% or higher, preferably 99% or higher, is used. Note that heating conditions equivalent to those in Step S13 can be employed in a later-described heating step other than Step S13.

### <Step S14>

Through the above steps, a composite oxide containing the transition metal (LiMO₂) can be obtained in Step S14 shown in FIG. 8. The composite oxide needs to have a crystal structure of a lithium composite oxide represented by LiMO₂, but the composition is not strictly limited to Li:M:O=1:1:2. In the case where cobalt is used as the transition metal, the composite oxide is referred to as a composite oxide containing cobalt and is represented by LiCoO₂. Note that the composition is not strictly limited to Li:Co:O=1:1:2.

Although the example is described where the composite oxide is fabricated by a solid phase method as in Step S11 to Step S14, the composite oxide may be fabricated by a coprecipitation method. Alternatively, the composite oxide may be fabricated by a hydrothermal method.

### <Step S20>

An additive element X may be added to the composite oxide as long as a layered rock-salt crystal structure can be obtained. A step of adding the additive element is described.

In Step S20 shown in FIG. 8, an additive element source (X source) to be added to the composite oxide is prepared. A lithium source may be prepared together with the additive element source.

As the additive element, one or more selected from nickel, cobalt, magnesium, calcium, chlorine, fluorine, aluminum, manganese, titanium, zirconium, yttrium, vanadium, iron, chromium, niobium, lanthanum, hafnium, zinc, silicon, sulfur, phosphorus, boron, and arsenic can be used. As the additive element, one or both of bromine and beryllium can be used. Note that the aforementioned additive elements are more suitably used because bromine and beryllium are elements having toxicity to living things.

For the addition of the additive element X, a solid phase method, a liquid phase method such as a sol-gel method, a sputtering method, an evaporation method, a CVD (chemical vapor deposition) method, a PLD (pulsed laser deposition) method, or the like can be used.

When magnesium is selected as the additive element, the additive element source can be referred to as a magnesium source. As the magnesium source, magnesium fluoride, magnesium oxide, magnesium hydroxide, magnesium carbonate, or the like can be used. Two or more of the above magnesium sources may be used.

When fluorine is selected as the additive element, the additive element source can be referred to as a fluorine source. As the fluorine source, for example, lithium fluoride (LiF), magnesium fluoride (MgF₂), aluminum fluoride (AlF₃), titanium fluoride (TiF₄), cobalt fluoride (CoF₂ and CoF₃), nickel fluoride (NiF₂), zirconium fluoride (ZrF₄), vanadium fluoride (VF₅), manganese fluoride, iron fluoride, chromium fluoride, niobium fluoride, zinc fluoride (ZnF₂), calcium fluoride (CaF₂), sodium fluoride (NaF), potassium fluoride (KF), barium fluoride (BaF₂), cerium fluoride (CeF₂), lanthanum fluoride (LaF₃), sodium aluminum hexafluoride (Na₃AlF₆), or the like can be used. Among them, lithium fluoride, which has a relatively low melting point of 848° C., is preferable because it is easily melted in a heating step described later.

Magnesium fluoride can be used as both the fluorine source and the magnesium source. Lithium fluoride can be used as both the fluorine source and the lithium source. Another example of the lithium source used in Step S20 is lithium carbonate.

The fluorine source may be a gas, and for example, fluorine (F₂), carbon fluoride, sulfur fluoride, oxygen fluoride (OF₂, O₂F₂, O₃F₂, O₄F₂, or O₂F), or the like may be used and mixed in the atmosphere in a heating step described later. Two or more of the above fluorine sources may be used.

In this embodiment, lithium fluoride (LiF) is prepared as the fluorine source, and magnesium fluoride (MgF₂) is prepared as the fluorine source and the magnesium source. When lithium fluoride and magnesium fluoride are mixed at approximately LiF:MgF₂=65:35 (molar ratio), the effect of lowering the melting point becomes the highest. On the other hand, when the amount of lithium fluoride increases, cycle performance might deteriorate because of too large an amount of lithium. Therefore, the molar ratio of lithium fluoride to magnesium fluoride is preferably LiF:MgF₂=x:1 (0≤x≤1.9), further preferably LiF:MgF₂=x:1 (0.1≤x≤0.5), still further preferably LiF:MgF₂=x:1 (x=0.33 and the neighborhood thereof). Note that the neighborhood means a value greater than 0.9 times and less than 1.1 times a certain value.

Next, as the additive element source (X source), the magnesium source and the fluorine source are ground and mixed. This step can be performed under any of the conditions for the grinding and mixing selected from those described for Step S12.

Then, a heating step may be performed as needed. Any of the heating conditions described for Step S13 can be selected to perform the heating step. The heating time is preferably longer than or equal to 2 hours and the heating temperature is preferably higher than or equal to 800° C. and lower than or equal to 1100° C. The materials ground and mixed in the above step are collected, so that the additive element source (X source) can be obtained. Note that the obtained additive element source is formed of a plurality of starting materials and can be referred to as a mixture. Note that the obtained additive element source is referred to as a mixture even when being formed of one kind of starting material.

As for the particle diameter of the mixture, the D50 (median diameter) is preferably greater than or equal to 600 nm and less than or equal to 20 μm, further preferably greater than or equal to 1 μm and less than or equal to 10 μm. Also when one kind of material is used as the additive element source, the D50 (median diameter) is preferably greater than or equal to 600 nm and less than or equal to 20 μm, further preferably greater than or equal to 1 μm and less than or equal to 10 μm.

When mixed with a composite oxide in a later step, the mixture pulverized to such a small size is easily attached to surfaces of composite oxide particles uniformly. The mixture is preferably attached to the surfaces of the composite oxides uniformly, in which case at least magnesium is easily distributed in or diffused to the surface portions of the composite oxides uniformly after heating. The surface portion refers to a region that is within 50 nm, preferably within 35 nm, further preferably within 20 nm in depth from the surface toward the inner portion, and most preferably a region within 10 nm in depth from the surface toward the inner portion. The region where magnesium is distributed can also be referred to as a surface portion. When there is a region not containing magnesium in the surface portion, the positive electrode active material might be less likely to have the O3′ type crystal structure, which is described later, in a charged state.

Although the example where two kinds of additive element sources, which are the magnesium source and the fluorine source, are prepared is described above, three or more kinds of additive element sources may be added to the composite oxide.

For example, as four kinds of additive element sources, a magnesium source (Mg source), a fluorine source (F source), a nickel source (Ni source), and an aluminum source (Al source) can be prepared. Note that the magnesium source and the fluorine source can be selected from the compounds and the like described above. As a nickel source, nickel oxide, nickel hydroxide, or the like can be used. As the aluminum source, aluminum oxide, aluminum hydroxide, or the like can be used.

### <Step S31>

Next, in Step S31 shown in FIG. 8, the composite oxide and the additive element source (X source) are mixed. The ratio of the number M of the transition metal atoms in the composite oxide containing lithium, the transition metal, and oxygen to the number Mg of magnesium atoms in the additive element source (X source) is preferably M:Mg=100:y (0.1≤y≤6), further preferably M:Mg=100:y (0.3≤y≤3).

The conditions of the mixing in Step S31 are preferably milder than those of the mixing in Step S12 in order not to damage the composite oxide particles. For example, conditions with a lower rotation frequency or shorter time than the mixing in Step S12 are preferable. In addition, it can be said that the dry process has a milder condition than the wet process. As a means for mixing, a ball mill, a bead mill, or the like can be used, for example. When a ball mill is used, zirconia balls are preferably used as media, for example.

In this embodiment, the mixing is performed with a ball mill using zirconia balls with a diameter of 1 mm by a dry process at 150 rpm for 1 hour. The mixing step is performed in a dry room the dew point of which is higher than or equal to −100° C. and lower than or equal to −10° C.

### <Step S32>

Next, in Step S32 in FIG. 8, the materials mixed in the above manner are collected, whereby a mixture 903 is obtained. At the time of collection, the materials may be made to pass through a sieve as needed after being crushed.

Note that in this embodiment, the method is described in which lithium fluoride as the fluorine source and magnesium fluoride as the magnesium source are added afterward to the composite oxide. However, the present invention is not limited to the above method. The magnesium source, the fluorine source, and the like may be added to the lithium source and the transition metal source in Step S11, i.e., at the stage of the starting materials of the composite oxide. Then, the heating in Step S13 is performed, so that LiMO₂ to which magnesium and fluorine are added can be obtained. In this case, there is no need to separate steps of Step S11 to Step S14 and steps of Step S31 to Step S33. This method can be regarded as being simple and highly productive.

Alternatively, lithium cobalt oxide to which magnesium and fluorine are added in advance may be used. When a lithium cobalt oxide to which magnesium and fluorine are added is used, steps of Step S11 to Step S32 and Step S20 can be skipped. This method can be regarded as being simple and highly productive.

Alternatively, in accordance with Step S20, a magnesium source and a fluorine source may be further added to the lithium cobalt oxide to which magnesium and fluorine are added in advance. Alternatively, a magnesium source, a fluorine source, a nickel source, and an aluminum source may be further added to the lithium cobalt oxide to which magnesium and fluorine are added in advance.

### <Step S33>

Then, in Step S33 shown in FIG. 8, the mixture 903 is heated. For the heating, any of the heating conditions described for Step S13 can be selected. The heating time is preferably longer than or equal to two hours.

Here, a supplementary explanation of the heating temperature is provided. The lower limit of the heating temperature in Step S33 needs to be higher than or equal to the temperature at which a reaction between the composite oxide (LiMO₂) and the additive element source proceeds. The temperature at which the reaction proceeds is the temperature at which interdiffusion of the elements included in LiMO₂ and the additive element source occurs, and may be lower than the melting temperatures of these materials. It is known that in the case of an oxide as an example, solid phase diffusion occurs at the Tamman temperature Td (0.757 times the melting temperature Tₘ). Accordingly, it is only required that the heating temperature in Step S33 be higher than or equal to 500° C.

Needless to say, the reaction more easily proceeds at a temperature higher than or equal to the temperature at which at least part of the mixture 903 is melted. In the case where LiF and MgF₂ are included as the additive element source, the eutectic point of LiF and MgF₂ is around 742° C., and the lower limit of the heating temperature in Step S33 is preferably higher than or equal to 742° C.

The mixture 903 obtained by mixing such that LiCoO₂:LiF:MgF₂=100:0.33:1 (molar ratio) exhibits an endothermic peak at around 830° C. in differential scanning calorimetry measurement (DSC measurement). Thus, the lower limit of the heating temperature is further preferably higher than or equal to 830° C.

A higher heating temperature is preferable because it facilitates the reaction, shortens the heating time, and enables high productivity.

The upper limit of the heating temperature is lower than the decomposition temperature of LiMO₂ (the decomposition temperature of LiCoO₂ is 1130° C.). At around the decomposition temperature, a slight amount of LiMO₂ might be decomposed. Thus, the heating temperature is preferably lower than or equal to 1000° C., further preferably lower than or equal to 950° C., and further preferably lower than or equal to 900° C.

In view of the above, the heating temperature in Step S33 is preferably higher than or equal to 500° C. and lower than or equal to 1130° C., further preferably higher than or equal to 500° C. and lower than or equal to 1000° C., still further preferably higher than or equal to 500° C. and lower than or equal to 950° C., and yet still further preferably higher than or equal to 500° C. and lower than or equal to 900° C. Furthermore, the heating temperature is preferably higher than or equal to 742° C. and lower than or equal to 1130° C., further preferably higher than or equal to 742° C. and lower than or equal to 1000° C., still further preferably higher than or equal to 742° C. and lower than or equal to 950° C., and yet still further preferably higher than or equal to 742° C. and lower than or equal to 900° C. Furthermore, the heating temperature is higher than or equal to 800° C. and lower than or equal to 1100° C., preferably higher than or equal to 830° C. and lower than or equal to 1130° C., further preferably higher than or equal to 830° C. and lower than or equal to 1000° C., still further preferably higher than or equal to 830° C. and lower than or equal to 950° C., and yet still further preferably higher than or equal to 830° C. and lower than or equal to 900° C. Note that the heating temperature in Step S33 is preferably higher than that in Step S13.

In addition, at the time of heating the mixture 903, the partial pressure of fluorine or a fluoride originating the fluorine source or the like is preferably controlled to be within an appropriate range.

In the fabrication method described in this embodiment, some of the materials, e.g., LiF as the fluorine source, function as a flux in some cases. Owing to this function, the heating temperature can be lower than the decomposition temperature of the composite oxide (LiMO₂), e.g., a temperature higher than or equal to 742° C. and lower than or equal to 950° C., which allows distribution of the additive element such as magnesium in the surface portion and fabrication of the positive electrode active material having favorable characteristics.

However, since LiF in a gas phase has a specific gravity less than that of oxygen, heating might volatilize or sublimate LiF and in that case, LiF in the mixture 903 decreases. As a result, the function of a flux deteriorates. Thus, heating needs to be performed while volatilization or sublimation of LiF is inhibited. Note that even when LiF is not used as the fluorine source or the like, Li at the surface of LiMO₂ and F of the fluorine source might react to produce LiF, which might volatilize or sublimate. Therefore, the volatilization or sublimation needs to be inhibited also when a fluoride having a higher melting point than LiF is used.

In view of this, the mixture 903 is preferably heated in an atmosphere containing LiF, i.e., the mixture 903 is preferably heated in a state where the partial pressure of LiF in a heating furnace is high. Such heating can inhibit volatilization or sublimation of LiF in the mixture 903.

The heating in this step is preferably performed such that the particles of the mixture 903 are not adhered to each other. Adhesion of the particles of the mixture 903 during the heating might decrease the area of contact with oxygen in the atmosphere and inhibit a path of diffusion of the additive element (e.g., fluorine), thereby hindering distribution of the additive element (e.g., magnesium) in the surface portion.

It is considered that uniform distribution of the additive element (e.g., fluorine) in the surface portion leads to a smooth positive electrode active material with little unevenness. In view of this, the particles are preferably not adhered to each other.

In the case of using a rotary kiln for the heating, the flow rate of an oxygen-containing atmosphere in the kiln is preferably controlled. For example, the flow rate of an oxygen-containing atmosphere is preferably set low, or no flowing of an atmosphere is preferably performed after an atmosphere is purged first and an oxygen atmosphere is introduced into the kiln. Flowing of oxygen is not preferable because it might cause evaporation of the fluorine source, which prevents maintaining the smoothness of the surface.

In the case of using a roller hearth kiln for the heating, the mixture 903 can be heated in an atmosphere containing LiF with the container containing the mixture 903 covered with a lid, for example.

A supplementary explanation of the heating time is provided. The heating time is changed depending on conditions, such as the heating temperature, and the particle size and composition of LiMO₂ in Step S14. In the case where the particle size is small, the heating is preferably performed at a lower temperature or for a shorter time than the case where the particle size is large, in some cases.

When the median diameter (D50) of the composite oxide (LiMO₂) in Step S14 in FIG. 8 is approximately 12 μm, the heating temperature is preferably higher than or equal to 600° C. and lower than or equal to 950° C., for example. The heating time is preferably longer than or equal to 3 hours, further preferably longer than or equal to 10 hours, still further preferably longer than or equal to 60 hours, for example. Note that the temperature decreasing time after the heating is, for example, preferably longer than tor equal to 10 hours and shorter than or equal to 50 hours.

When the median diameter (D50) of the composite oxide (LiMO₂) in Step S14 is approximately 5 μm, the heating temperature is preferably higher than or equal to 600° C. and lower than or equal to 950° C., for example. The heating time is preferably longer than or equal to 1 hour and shorter than or equal to 10 hours, further preferably approximately 2 hours, for example. Note that the temperature decreasing time after the heating is, for example, preferably longer than or equal to 10 hours and shorter than or equal to 50 hours.

### <Step S34>

Next, in Step S34 shown in FIG. 8, the heated material is collected and then crushed as need to obtain the positive electrode active material 100. Here, the collected particles are preferably made to pass through a sieve.

Through the above process, the positive electrode active material 100 of one embodiment of the present invention can be fabricated.

### <<Fabrication Method 2 of Positive Electrode Active Material>>

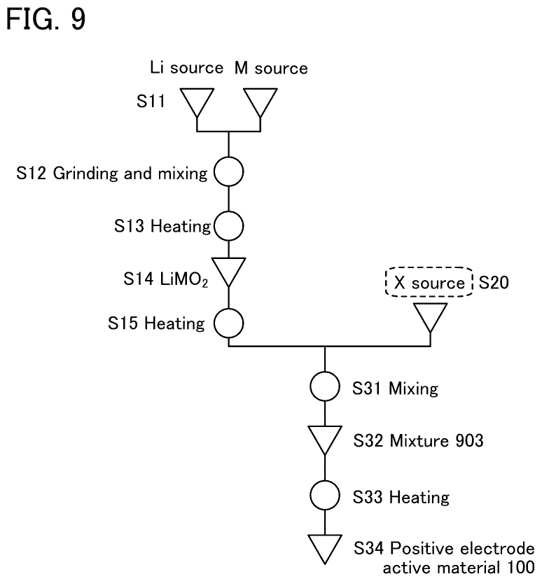

As shown in FIG. 9, a heating step may be added as Step S15 after Step S14. A fabrication method including this step is described.

### <Step S15>

Step S11 to Step S14 shown in FIG. 9 are similar to Step S11 to Step S14 shown in FIG. 8. In Step S15 shown in FIG. 9, the above composite oxide is heated. The heating in Step S15 is the first heating performed on the composite oxide, and thus is sometimes referred to as initial heating. Through the initial heating, the surface of the composite oxide becomes smooth. Having a smooth surface refers to a state where the composite oxide has little unevenness and is rounded as a whole and its corner portion is rounded. Having a smooth surface also refers to a state where few foreign matters are attached to a surface. Foreign matters are deemed to cause unevenness and are preferably not attached to a surface. The composite oxide can also have high hardness when having a smooth surface.

The initial heating refers to heating after the composite oxide is completed. When the initial heating is performed aiming at smoothing a surface, an additive element can be added uniformly and a continuous barrier layer can be formed.

For the initial heating, there is no need to prepare a lithium compound source.

For the initial heating, there is no need to prepare an additive element source.

For the initial heating, a flux agent does not need to be prepared.

The initial heating is heating performed before addition of an additive element, and is referred to as preheating or pretreatment in some cases.

The initial heating can reduce impurities in the composite oxide completed in Step 14.

The heating conditions in this step can be freely set as long as the heating makes the surface of the above composite oxide smooth. For example, any of the heating conditions described for Step S13 can be selected. Additionally, the heating temperature in this step is preferably lower than that in Step S13 so that the crystal structure of the composite oxide is maintained. The heating time in this step may be shorter than that in Step S13 so that the crystal structure of the composite oxide is maintained. For example, the heating is preferably performed at a temperature of higher than or equal to 700° C. and lower than or equal to 1000° C. for approximately 2 hours.

In the composite oxide, a temperature difference between the surface and the inner portion of the composite oxide might be caused by the heating in Step S13. The temperature difference sometimes induces differential shrinkage. It can also be deemed that the temperature difference leads to a fluidity difference between the surface and the inner portion, thereby causing differential shrinkage. The energy involved in differential shrinkage causes a difference in internal stress in the composite oxide. The difference in internal stress is also called distortion, and the above energy is sometimes referred to as distortion energy. The internal stress is eliminated by the initial heating in Step S15 and in other words, the distortion energy is probably equalized by the initial heating in Step S15. When the distortion energy is equalized, the distortion in the composite oxide is relieved. Thus, it is deemed that Step S15 makes the surface of the composite oxide smooth. In other words, it is deemed that Step S15 reduces the differential shrinkage caused in the composite oxide to make the surface of the composite oxide smooth. This is also rephrased as modification of the surface.

Such differential shrinkage might cause a micro shift in the composite oxide such as a shift in a crystal. To reduce the shift, the initial heating is preferably performed. Performing the initial heating can distribute a shift uniformly in the composite oxide. When the shift is distributed uniformly, the surface of the composite oxide might become smooth. “Shift is distributed uniformly” is also rephrased as “crystal grains are aligned”. In other words, it is deemed that Step S15 reduces the shift due to a crystal or the like which is caused in the composite oxide to make the surface of the composite oxide smooth.

The use of a composite oxide with a smooth surface as a positive electrode active material can prevent cracking of the positive electrode active material, thereby reducing deterioration after a cycle test.

It can be said that when surface unevenness information in one cross section of a composite oxide is converted into numbers with measurement data, a smooth surface of the composite oxide has a surface roughness of at least less than or equal to 10 nm. The one cross section is, for example, a cross section acquired in observation using a scanning transmission electron microscope (STEM).

Note that when Step S15 is performed on the pre-synthesized composite oxide containing lithium, a transition metal, and oxygen, a composite oxide with a smooth surface can be obtained.

The initial heating might reduce the amount of lithium in the composite oxide. The reduction in the amount of lithium might promote entry of an additive element into the composite oxide when the additive element source is added after Step S20.

Through the above steps, the positive electrode active material 100 of one embodiment of the present invention can be fabricated. The positive electrode active material of one embodiment of the present invention has a smooth surface.

### <<Fabrication Method 3 of Positive Electrode Active Material>>

Next, as one embodiment of the present invention, a method different from the fabrication methods 1 and 2 of the positive electrode active material will be described.

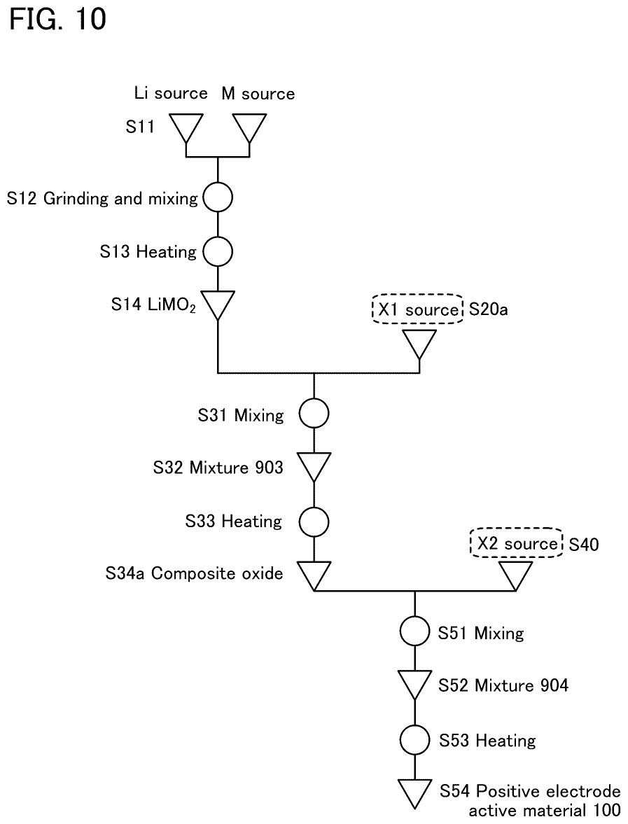

Steps S11 to S14 in FIG. 10 are performed as in FIG. 8 to prepare a composite oxide (LiMO₂). Note that with reference to FIG. 9, Step S15 may be added after Step S14 to prepare a composite oxide (LiMO₂) with a smooth surface.

As described above, the additive element X may be added to the composite oxide as long as a layered rock-salt crystal structure can be obtained. A fabrication method 3 here describes the addition of the additive element divided into two or more steps.

### <Step S20a>

First, in Step S20a shown in FIG. 10, a first additive element source (X1 source) is prepared. As the X1 source, any one selected from the additive elements X described for Step S20 shown in FIG. 8 can be used.

For the addition of the first additive element X1, a solid phase method, a liquid phase method such as a sol-gel method, a sputtering method, an evaporation method, a CVD (chemical vapor deposition) method, a PLD (pulsed laser deposition) method, or the like can be used.

Here, as the first additive element source (X1 source), a magnesium source (Mg source) and a fluorine source (F source) are prepared. Next, with reference to Step S31 to Step S33 shown in FIG. 8, grinding, mixing, heating, and the like of the magnesium source and the fluorine source are performed as appropriate, so that the first additive element source (X1 source) can be obtained.

That is, Step S31 to Step S33 shown in FIG. 10 can be performed in a manner similar to that of Step S31 to Step S33 shown in FIG. 8.

### <Step S34a>

Next, the material heated in Step S33 is collected to fabricate a composite oxide containing the first additive element X1. This composite oxide is called a second composite oxide to be distinguished from the composite oxide in Step S14.

### <Step S40>

In Step S40 shown in FIG. 10, a second additive element source (X2 source) is prepared. As the X2 source, any one selected from the additive elements X described for Step S20 shown in FIG. 8 can be used.

For the addition of the second additive element X2, a solid phase method, a liquid phase method such as a sol-gel method, a sputtering method, an evaporation method, a CVD (chemical vapor deposition) method, a PLD (pulsed laser deposition) method, or the like can be used.

Here, in the case where a sol-gel method is used for the addition of the second additive element X2, a solvent used for the sol-gel method is prepared in addition to the second additive element source (X2 source). In the sol-gel method, a metal alkoxide can be used as a metal source and alcohol can be used as the solvent, for example. In the case of adding aluminum, for example, aluminum isopropoxide can be used as the metal source and isopropanol(2-propanol) can be used as the solvent. For example, in the case of adding zirconium, zirconium(IV) tetraisopropoxide can be used as the metal source and isopropanol can be used as the solvent.

In Step S40 shown in FIG. 10, nickel and aluminum can be used as the second additive element X2, and alkoxides of nickel and aluminum are prepared.

In Step S40 shown in FIG. 10, with reference to Step S20 shown in FIG. 8, grinding, mixing, heating, and the like are performed as appropriate, so that the second additive element source (X2 source) can be obtained.

In the case where a plurality of element sources are contained as the second additive element source, the plurality of element sources may be prepared by independently performing the steps up to and including the step of grinding. As a result, a plurality of second additive element sources (X2 sources) are independently prepared in Step S40.

For example, the second additive element source using a solid phase method and the second additive element source using a sol-gel method may be independently prepared. An example is described where a nickel source and an aluminum source are prepared by a wet process and a sol-gel method, respectively.

First, nickel hydroxide is prepared and ground to prepare a nickel source. Heating may be performed after grinding to remove a solvent.

Next, aluminum isopropoxide, zirconium tetrapropoxide, and isopropanol are prepared separately from the nickel source, and then stirring is performed. After that, filtration is performed for collection and drying under reduced pressure is performed at 70° C. for one hour to prepare an aluminum source.

### <Step S51 to Step S54>

Next, Step S51 to Step S53 shown in FIG. 10 can be performed under conditions similar to those of Step S31 to Step S34 shown in FIG. 8. Note that a mixture 904 is obtained in Step S52. Through the above steps, the positive electrode active material 100 of one embodiment of the present invention can be fabricated in Step S54.

As shown in FIG. 10, in the fabrication method 3, introduction of the additive element to the composite oxide is divided into introduction of the first additive element X1 and that of the second additive element X2. When the introduction is divided, the additive elements can have different concentration profiles in the depth direction. For example, the first additive element can be introduced such that its concentration is higher in the surface portion than in the inner portion, and the second additive element can be introduced such that its concentration is higher in the inner portion than in the surface portion.

### <<Fabrication Method 4 of Positive Electrode Active Material>>

Next, as one embodiment of the present invention, a method different from the fabrication methods 1 to 3 of the positive electrode active material is described.

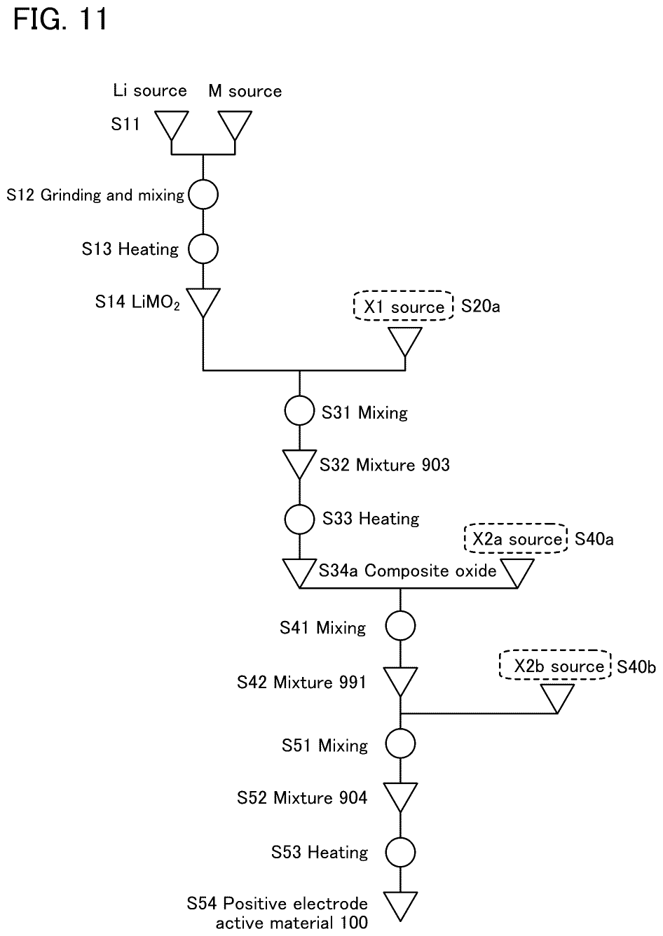

As described above, the additive element X may be added to the composite oxide as long as a layered rock-salt crystal structure can be obtained. In FIG. 11, Step S11 to Step S34a are performed as in FIG. 10. A fabrication method 4 here describes the addition of the second additive element (X2) divided into two or more steps.

### <Step S40a>

In Step S40a shown in FIG. 11, one of the second additive element sources (hereinafter, referred to as X2a source) is prepared. As the X2a source, any one selected from the additive elements X described for Step S20 shown in FIG. 8 can be used. For example, one or more selected from nickel, titanium, boron, zirconium, and aluminum can be suitably used as the X2a source.

For the addition of the additive element X2a source, a solid phase method, a liquid phase method such as a sol-gel method, a sputtering method, an evaporation method, a CVD (chemical vapor deposition) method, a PLD (pulsed laser deposition) method, or the like can be used.

FIG. 11 shows an example where nickel is used as the X2a source.

In Step S40a shown in FIG. 11, with reference to Step S20 shown in FIG. 8, grinding, mixing, heating, and the like are performed as appropriate, so that the X2a source can be obtained. For example, a nickel source is obtained as the X2a source by a solid phase method.

In the case where a plurality of additive element sources are prepared, grinding may be performed independently.

### <Step S40b>

In Step S40b shown in FIG. 11, the other of the second additive element sources (hereinafter, referred to as X2b source) can be obtained. For example, the X2b source is obtained by a sol-gel method. In the case where a sol-gel method is used for preparation in this manner, unlike in Step S40a, steps for preparations are preferably performed independently. A fabrication process of the X2b source by a sol-gel method is described.

In the case where a sol-gel method is used, a solvent used for the sol-gel method is prepared in addition to X2b. In the sol-gel method, a metal alkoxide can be used as a metal source and alcohol can be used as the solvent, for example. Aluminum isopropoxide can be used as aluminum alkoxide in the case of preparing an aluminum source, zirconium isopropoxide can be used as zirconium alkoxide in the case of preparing a zirconium source, and isopropanol can be used as the solvent.

Next, the aluminum alkoxide, the zirconium alkoxide, and the isopropanol are mixed (stirred). The sol-gel reaction may be progressed here, or the sol-gel reaction may be progressed in the next step. In the case where the sol-gel reaction is progressed, heating may be performed at the time of mixing. In this manner, a mixture (also referred to as a mixed solution) containing the aluminum source and the zirconium source is prepared as the X2b source.

### <Step S51 to Step S54>

Next, Steps S51 to S53 shown in FIG. 11 can be performed under conditions similar to those of Steps S31 to S33 shown in FIG. 8. The sol-gel reaction can be progressed in Step S53. Through the above steps, the positive electrode active material 100 of one embodiment of the present invention can be fabricated in Step S54. It is also possible to progress the sol-gel reaction in Step S53.

This embodiment can be used in combination with the other embodiments.

### Embodiment 6

In this embodiment, a fabrication process of a coated electrode for a positive electrode or a negative electrode is described.

The coated electrode refers to an electrode obtained by forming a positive electrode mixed agent (containing at least a positive electrode active material) on a positive electrode current collector or an electrode obtained by forming a negative electrode mixed agent (containing at least a negative electrode active material) on a negative electrode current collector. Each mixed agent includes a conductive material or a binder in some cases.

For example, the positive electrode active material described in the above embodiment, a conductive material, and a binder are mixed, and a dispersion medium is added to the mixture. After the addition of the dispersion medium, further mixing is performed to form a slurry. The viscosity of the slurry is preferably higher than or equal to 80 pa-s and lower than or equal to 130 pa-s.

The slurry is applied on a positive electrode current collector, and then drying is performed to volatilize or evaporate at least the dispersion medium. After that, the slurry may be rolled with pressure. The coated electrode is completed in this manner. The thickness of the coated electrode is preferably greater than or equal to 1 μm and less than or equal to 10 μm. The electrode density of the coated electrode is preferably greater than or equal to 3.0 g/cm³ and less than or equal to 5.0 g/cm³.

Although the case of the positive electrode is described, the negative electrode can be fabricated in a similar manner.

This embodiment can be used in combination with the other embodiments.

### Embodiment 7

In this embodiment, a fabrication process of a secondary battery is described.

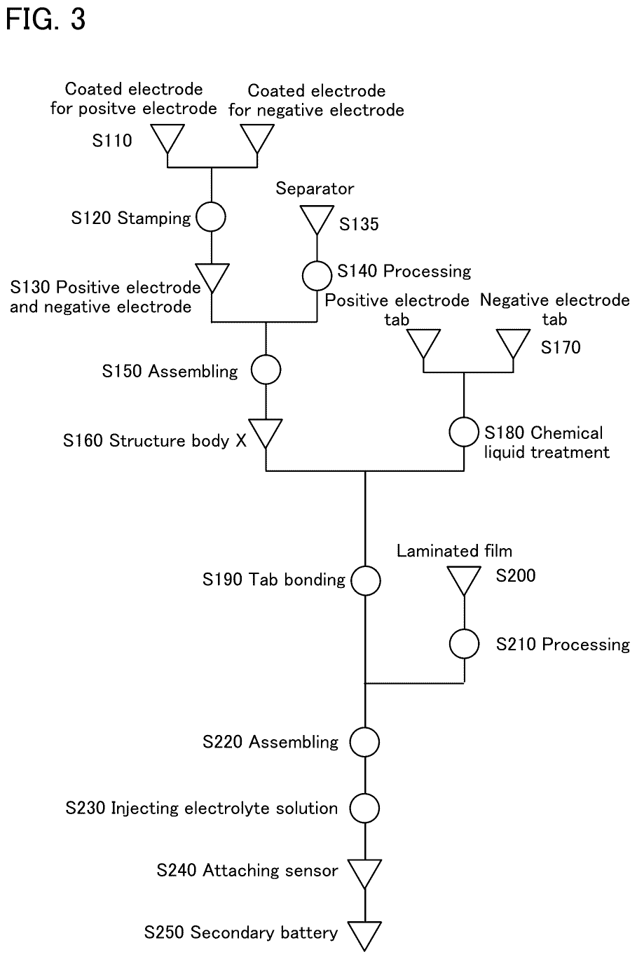

FIG. 3 shows an example of a fabrication process of a secondary battery. In Step S110, a coated electrode for a positive electrode and a coated electrode for a negative electrode are prepared. Each coated electrode can be fabricated in accordance with the above embodiment, for example.

In Step S120 in FIG. 3, a step of stamping out the coated electrode into a desired shape is performed. A tab region is provided at a position protruding from a rectangular positive electrode or negative electrode, and the one side length of the tab region is greater than or equal to ⅓ and less than or equal to ⅕ of the one side length of the positive electrode or the negative electrode. In the stamping step, a region where the tab is bonded (a tab region) is brought into a conductive state. For example, an insulating film or the like in the tab region stamped out at a predetermined position is removed by a chemical liquid. As the chemical liquid, acetone, ethanol, or N-methyl-2-pyrrolidone (NMP) can be used. In this manner, the positive electrode and the negative electrode that are included in a secondary battery can be obtained in Step S130.

Next, a separator is prepared as shown in Step S135 in FIG. 3, and the separator is processed in Step S140. For example, it is preferable that a cut-out separator be folded in half and processed into a bag-like separator with welded two sides. The width of the welded region is preferably greater than or equal to 3 nm and less than or equal to 10 mn. Heat of higher than or equal to 120° C. and lower than or equal to 170° C., preferably higher than or equal to 130° C. and lower than or equal to 150° C. is applied for welding in some cases; at this time, placing a metal foil in a region not to be welded (a region that forms a bag-like shape) can prevent welding in an undesired region.

Then, as shown in Step S150 in FIG. 3, the positive electrode, the negative electrode, and the separator are assembled. For example, one of the positive electrode and the negative electrode is put into the bag-like separator, and the separator and the other of the positive electrode and the negative electrode are made to overlap with each other. For example, 10 positive electrodes and 10 negative electrodes, each of which is single-side coated, are prepared, and 5 separators are prepared. In the case where the positive electrode is put into the separator, two positive electrodes are put with the positive electrode current collectors facing each other. The other positive electrodes are put into the other separators in the same manner. Two negative electrodes are placed between the separators with the negative electrode current collectors facing each other. A set of two separators are positioned on the outermost surfaces, and one negative electrode is placed on each outermost surface with the negative electrode active material facing the separator. In this manner, a structure body X can be assembled as shown in Step S160. In the structure body X, the tab regions are preferably bonded to each other. For example, the tab regions of the positive electrodes and the tab regions of the negative electrodes are bonded with an ultrasonic metal bonding apparatus.

Next, as shown in Step S170 in FIG. 3, a positive electrode tab and a negative electrode tab are prepared. As shown in Step S180, chemical liquid treatment is performed to remove an insulating film or the like from the positive electrode tab and the negative electrode tab. As the chemical liquid, acetone, ethanol, or NMP can be used.

As shown in Step S190 in FIG. 3, the positive electrode tab and the negative electrode tab are bonded to the structure body X. The positive electrode tab and the negative electrode tab are bonded to the corresponding tab regions that are bonded in Step S160 with an ultrasonic metal bonding apparatus.

Then, a laminated film is prepared as shown in Step S200 in FIG. 3 and the laminated film is processed as shown in Step S210. In the processing, for example, a depressed portion with a depth of greater than or equal to 1 mm and less than or equal to 10 mm, preferably greater than or equal to 1.5 mm and less than or equal to 3 mm is formed in part of the laminated film.

Assembling is performed as shown in Step S220 in FIG. 3. For example, the structure body X to which the tabs are bonded is stored in the depressed portion, the laminated film is folded, and at least two opposing sides are welded. Heat of higher than or equal to 150° C. and lower than or equal to 190° C., preferably higher than or equal to 170° C. and lower than or equal to 180° C. is applied. Furthermore, welding is preferably performed in a vacuum atmosphere.

Next, as shown in Step S230 in FIG. 3, an electrolyte solution is injected. The electrolyte solution is preferably injected in a vacuum atmosphere. The remaining portion of the laminated film is welded. As shown in Step S240, a sensor member is attached to the outer side of the laminated film. The above embodiment can be referred to for the sensor member.

Consequently, as shown in Step S250 in FIG. 3, the laminated secondary battery including the sensor is completed.

This embodiment can be used in appropriate combination with the other embodiments.

### Embodiment 8

In this embodiment, structure examples of a secondary battery are described.

### <Coin-Type Secondary Battery>

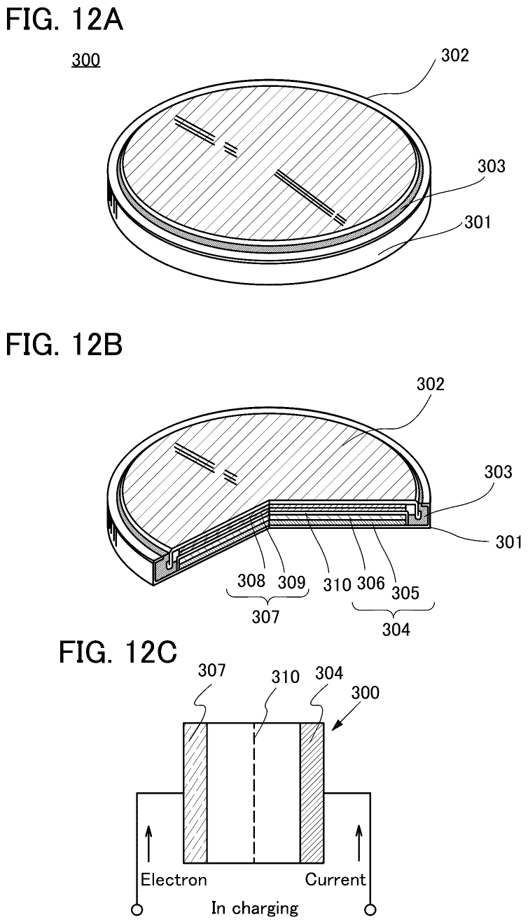

First, an example of a coin-type secondary battery is described. FIG. 12A is an external view of a coin-type (single-layer flat type) secondary battery, and FIG. 12B is a cross-sectional view thereof. The coin-type secondary battery can be provided with a sensor member.

In a coin-type secondary battery 300, a positive electrode can 301 doubling as a positive electrode terminal and a negative electrode can 302 doubling as a negative electrode terminal are insulated from each other and sealed by a gasket 303 made of polypropylene or the like. A positive electrode 304 includes a positive electrode current collector 305 and a positive electrode active material layer 306 provided in contact with the positive electrode current collector 305. A negative electrode 307 includes a negative electrode current collector 308 and a negative electrode active material layer 309 provided in contact with the negative electrode current collector 308.

Note that only one surface of each of the positive electrode 304 and the negative electrode 307 used for the coin-type secondary battery 300 is provided with an active material layer.

For the positive electrode can 301 and the negative electrode can 302, a metal having corrosion resistance to an electrolyte solution, such as nickel, aluminum, or titanium, an alloy of such a metal, or an alloy of such a metal and another metal (e.g., stainless steel) can be used. Alternatively, the positive electrode can 301 and the negative electrode can 302 are preferably covered with nickel, aluminum, or the like in order to prevent corrosion due to the electrolyte solution. The positive electrode can 301 and the negative electrode can 302 are electrically connected to the positive electrode 304 and the negative electrode 307, respectively.

The negative electrode 307, the positive electrode 304, and a separator 310 are immersed in the electrolyte. Then, as illustrated in FIG. 12B, the positive electrode 304, the separator 310, the negative electrode 307, and the negative electrode can 302 are stacked in this order with the positive electrode can 301 positioned at the bottom, and the positive electrode can 301 and the negative electrode can 302 are subjected to pressure bonding with the gasket 303 therebetween. In such a manner, the coin-type secondary battery 300 is manufactured.

When the positive electrode active material described in the above embodiment is used in the positive electrode 304, the coin-type secondary battery 300 with high charge and discharge capacity and excellent cycle performance can be obtained.

Here, a current flow in charging a secondary battery is described with reference to FIG. 12C. When a secondary battery using lithium is regarded as a closed circuit, movement of lithium ions and the current flow are in the same direction. Note that in the secondary battery using lithium, the anode and the cathode interchange in charging and discharging, and the oxidation reaction and the reduction reaction interchange; hence, an electrode with a high reaction potential is called a positive electrode and an electrode with a low reaction potential is called a negative electrode. For this reason, in this specification, the positive electrode is referred to as a “positive electrode” or a “plus electrode” and the negative electrode is referred to as a “negative electrode” or a “minus electrode” in all the cases where charging is performed, discharging is performed, a reverse pulse current is supplied, and a charge current is supplied. The use of the term “anode” or “cathode” related to an oxidation reaction or a reduction reaction might cause confusion because the anode and the cathode interchange in charging and discharging. Thus, the term “anode” or “cathode” is not used in this specification. If the term “anode” or “cathode” is used, it should be mentioned that the anode or the cathode is which of the one at the time of charging or the one at the time of discharging and corresponds to which of a positive (plus) electrode or a negative (minus) electrode.

Two terminals illustrated in FIG. 12C are connected to a charger, and the secondary battery 300 is charged. As the charging of the secondary battery 300 proceeds, a potential difference between electrodes increases.

### <Cylindrical Secondary Battery>

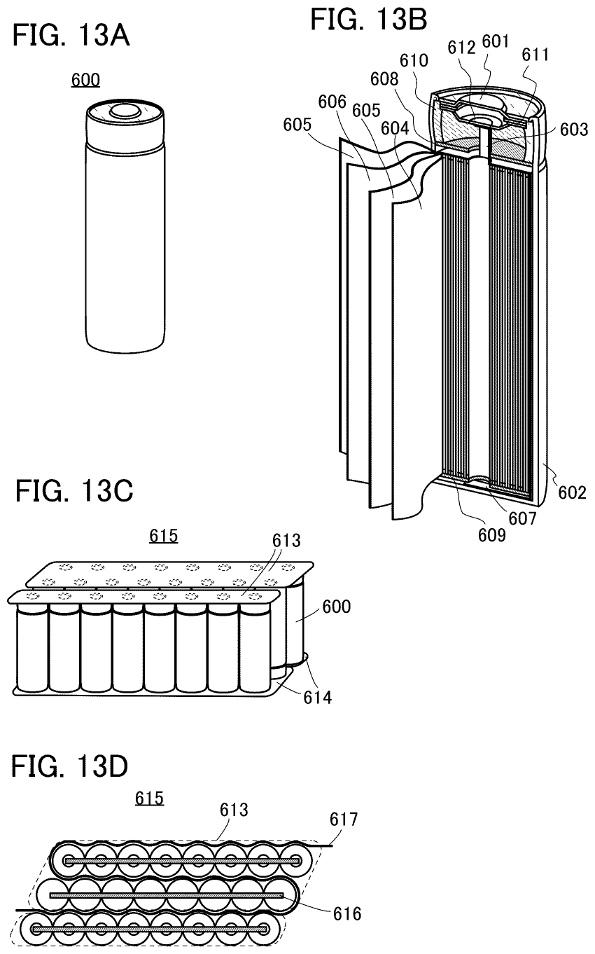

Next, an example of a cylindrical secondary battery is described with reference to FIG. 13A and FIG. 13B. FIG. 13A is an external view of a cylindrical secondary battery 600. FIG. 13B is a schematic cross-sectional view of the cylindrical secondary battery 600. The cylindrical secondary battery 600 includes, as illustrated in FIG. 13B, a positive electrode cap (battery lid) 601 on the top surface and a battery can (outer can) 602 on the side and the bottom surfaces. The positive electrode cap 601 and the battery can (outer can) 602 are insulated from each other by a gasket (insulating gasket) 610. The cylindrical secondary battery can also be provided with a sensor member.

Inside the battery can 602 having a hollow cylindrical shape, a battery element in which a strip-like positive electrode 604 and a strip-like negative electrode 606 are wound with a separator 605 interposed therebetween is provided. Although not illustrated, the battery element is wound around a center pin. One end of the battery can 602 is close and the other end thereof is open. For the battery can 602, a metal having corrosion resistance to an electrolyte solution, such as nickel, aluminum, or titanium, an alloy of such a metal, or an alloy of such a metal and another metal (e.g., stainless steel) can be used. Alternatively, the battery can 602 is preferably covered with nickel, aluminum, or the like in order to prevent corrosion due to the electrolyte solution. Inside the battery can 602, the battery element in which the positive electrode, the negative electrode, and the separator are wound is provided between a pair of insulating plates 608 and 609 that face each other. Furthermore, a nonaqueous electrolyte solution (not illustrated) is injected inside the battery can 602 provided with the battery element. As the nonaqueous electrolyte solution, a nonaqueous electrolyte solution that is similar to that of the coin-type secondary battery can be used.

Since a positive electrode and a negative electrode that are used for a cylindrical storage battery are wound, active materials are preferably formed on both surfaces of a current collector. A positive electrode terminal (positive electrode current collecting lead) 603 is connected to the positive electrode 604, and a negative electrode terminal (negative electrode current collecting lead) 607 is connected to the negative electrode 606. Both the positive electrode terminal 603 and the negative electrode terminal 607 can be formed using a metal material such as aluminum. The positive electrode terminal 603 and the negative electrode terminal 607 are resistance-welded to a safety valve mechanism 612 and the bottom of the battery can 602, respectively. The safety valve mechanism 612 is electrically connected to the positive electrode cap 601 through a PTC element (Positive Temperature Coefficient) 611. The safety valve mechanism 612 cuts off electrical connection between the positive electrode cap 601 and the positive electrode 604 when the internal pressure of the battery exceeds a predetermined threshold value. The PTC element 611, which serves as a thermally sensitive resistor whose resistance increases as temperature rises, limits the amount of current by increasing the resistance, in order to prevent abnormal heat generation. Barium titanate (BaTiO₃)-based semiconductor ceramics or the like can be used for the PTC element.

Furthermore, as illustrated in FIG. 13C, a plurality of secondary batteries 600 may be provided between a conductive plate 613 and a conductive plate 614 to form a module 615. The plurality of secondary batteries 600 may be connected in parallel, connected in series, or connected in series after being connected in parallel. With the module 615 including the plurality of secondary batteries 600, large electric power can be extracted.

FIG. 13D is a top view of the module 615. The conductive plate 613 is shown by a dotted line for clarity of the diagram. As illustrated in FIG. 13D, the module 615 may include a wiring 616 electrically connecting the plurality of secondary batteries 600 with each other. It is possible to provide the conductive plate over the wiring 616 to overlap with each other. In addition, a temperature control device 617 may be provided between the plurality of secondary batteries 600. The secondary batteries 600 can be cooled with the temperature control device 617 when overheated, whereas the secondary batteries 600 can be heated with the temperature control device 617 when cooled too much. Thus, the performance of the module 615 is less likely to be affected by the outside temperature. A heating medium included in the temperature control device 617 preferably has an insulating property and incombustibility.

When the positive electrode active material described in the above embodiment is used in the positive electrode 604, the cylindrical secondary battery 600 with high charge and discharge capacity and excellent cycle performance can be obtained.

### <Structure Examples of Secondary Battery>

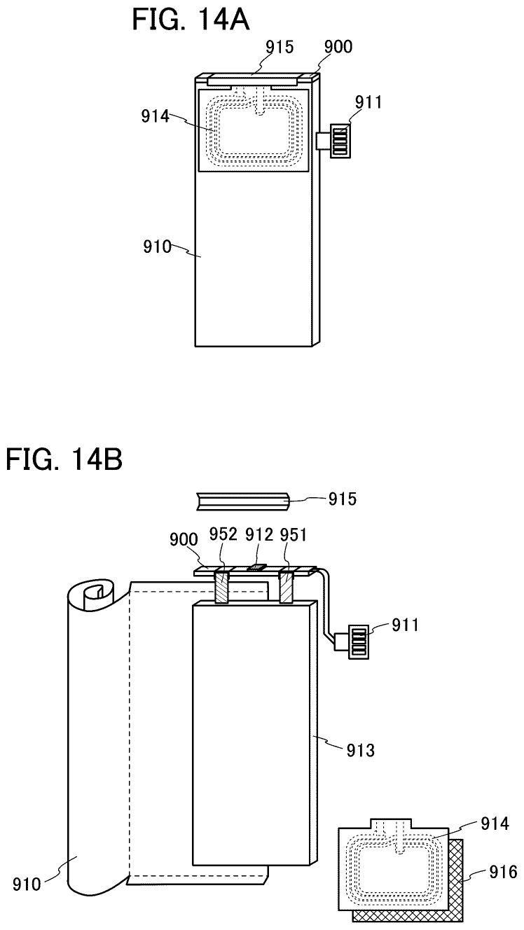

Other structure examples of secondary batteries are described with reference to FIG. 14 to FIG. 22.

FIG. 14A and FIG. 14B are external views of a battery pack. The battery pack includes a secondary battery 913 provided with a sensor member, and a circuit board 900. The secondary battery 913 is connected to an antenna 914 through the circuit board 900. A label 910 is attached to the secondary battery 913. In addition, as illustrated in FIG. 14B, the secondary battery 913 is connected to a terminal 951 and a terminal 952. The circuit board 900 is fixed with a seal 915.

The circuit board 900 includes a terminal 911 and a circuit 912. The terminal 911 is connected to the terminal 951, the terminal 952, the antenna 914, and the circuit 912. Note that a plurality of terminals 911 may be provided to serve as a control signal input terminal, a power supply terminal, and the like.

The circuit 912 may be provided on the rear surface of the circuit board 900. Note that the shape of the antenna 914 is not limited to coil shapes, and may be a linear shape or a plate shape, for example. An antenna such as a planar antenna, an aperture antenna, a traveling-wave antenna, an EH antenna, a magnetic-field antenna, or a dielectric antenna may be used. Alternatively, the antenna 914 may be a flat-plate conductor. The flat-plate conductor can serve as one of conductors for electric field coupling. That is, the antenna 914 may serve as one of two conductors of a capacitor. Thus, electric power can be transmitted and received not only by an electromagnetic field or a magnetic field but also by an electric field.

The battery pack includes a layer 916 between the antenna 914 and the secondary battery 913. The layer 916 has a function of blocking an electromagnetic field by the secondary battery 913, for example. As the layer 916, for example, a magnetic body can be used.

Note that the structure of the battery pack is not limited to that in FIG. 14.

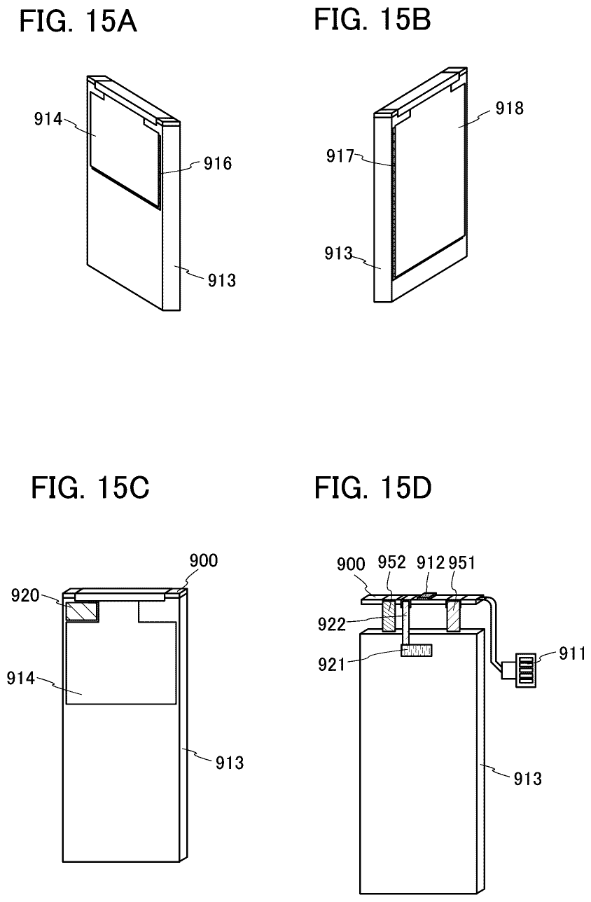

For example, as illustrated in FIG. 15A and FIG. 15B, in the battery pack, two opposite surfaces of the secondary battery 913 provided with the sensor member may be provided with respective antennas. FIG. 15A is an external view seen from one side of the opposite surfaces, and FIG. 15B is an external view seen from the other side of the opposite surfaces.

As illustrated in FIG. 15A, the antenna 914 is provided on one of the opposite surfaces of the secondary battery 913 with the layer 916 interposed therebetween, and as illustrated in FIG. 15B, an antenna 918 is provided on the other of the opposite surfaces of the secondary battery 913 with a layer 917 interposed therebetween. The layer 917 has a function of blocking an electromagnetic field by the secondary battery 913, for example. As the layer 917, for example, a magnetic body can be used.

With the above structure, both of the antenna 914 and the antenna 918 can be increased in size. The antenna 918 has a function of communicating data with an external device, for example. An antenna with a shape that can be used for the antenna 914, for example, can be used as the antenna 918. As a system for communication using the antenna 918 between the secondary battery and another device, a response method that can be used between the secondary battery and another device, such as NFC (near field communication), can be employed.

Alternatively, as illustrated in FIG. 15C, the secondary battery 913 illustrated in FIG. 15A and FIG. 15B may be provided with a display device 920. Note that for portions similar to those of the secondary battery illustrated in FIG. 15A and FIG. 15B, the description of the secondary battery illustrated in FIG. 15A and FIG. 15B can be appropriately referred to.

The display device 920 is electrically connected to the terminal 911 or the like, and the display device 920 may display, for example, an image showing whether charging is being carried out, an image showing the amount of stored power, or the like. As the display device 920, electronic paper, a liquid crystal display device, an electroluminescent (EL) display device, or the like can be used. For example, the use of electronic paper can reduce power consumption of the display device 920.

Alternatively, as illustrated in FIG. 15D, the secondary battery 913 illustrated in FIG. 15A and FIG. 15B may be provided with a sensor 921. The sensor 921 is electrically connected to the terminal 911 via a terminal 922. Note that for portions similar to those of the secondary battery illustrated in FIG. 15A and FIG. 15B, the description of the secondary battery illustrated in FIG. 15A and FIG. 15B can be appropriately referred to.

The sensor 921 has a function of measuring, for example, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays. With the sensor 921, for example, data on an environment (e.g., temperature) where the secondary battery is placed can be detected and stored in a memory inside the circuit 912.

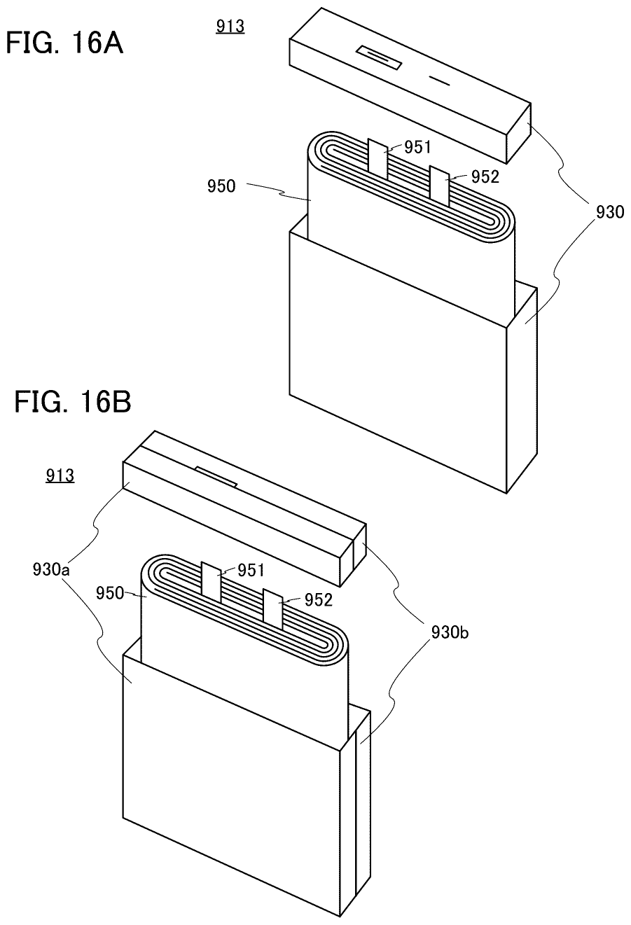

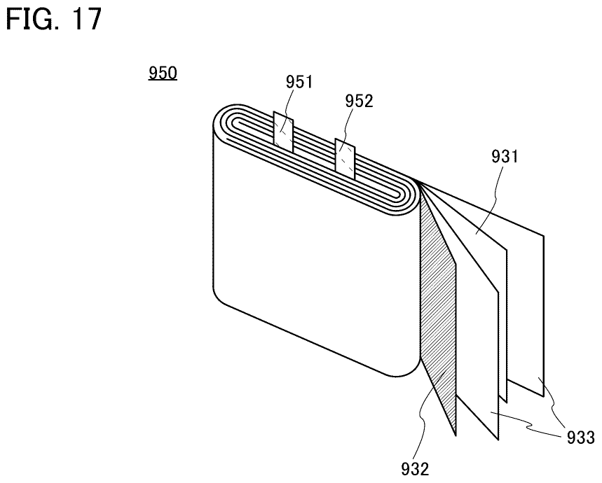

Furthermore, structure examples of the secondary battery 913 are described with reference to FIG. 16 and FIG. 17.

The secondary battery 913 illustrated in FIG. 16A includes a wound body 950 provided with the terminal 951 and the terminal 952 inside a housing 930. The wound body 950 is immersed in an electrolyte solution inside the housing 930. The terminal 952 is in contact with the housing 930. The use of an insulator or the like prevents contact between the terminal 951 and the housing 930. Note that in FIG. 16A, the housing 930 divided into pieces is illustrated for convenience; however, in the actual structure, the wound body 950 is covered with the housing 930 and the terminal 951 and the terminal 952 extend to the outside of the housing 930. For the housing 930, a metal material (e.g., aluminum) or a resin material can be used. The secondary battery including the wound body can also be provided with a sensor member.

Note that as illustrated in FIG. 16B, the housing 930 illustrated in FIG. 16A may be formed using a plurality of materials. For example, in the secondary battery 913 illustrated in FIG. 16B, a housing 930a and a housing 930b are bonded to each other, and the wound body 950 is provided in a region surrounded by the housing 930a and the housing 930b.

For the housing 930a, an insulating material such as an organic resin can be used. In particular, when a material such as an organic resin is used for the side on which an antenna is formed, blocking of an electric field from the secondary battery 913 can be inhibited. When an electric field is not significantly blocked by the housing 930a, an antenna such as the antenna 914 may be provided inside the housing 930a. For the housing 930b, a metal material can be used, for example.

FIG. 17 illustrates the structure of the wound body 950. The wound body 950 includes a negative electrode 931, a positive electrode 932, and separators 933. The wound body 950 is obtained by winding a sheet of a stack in which the negative electrode 931 overlaps with the positive electrode 932 with the separator 933 interposed therebetween. Note that a plurality of stacks each including the negative electrode 931, the positive electrode 932, and the separator 933 may be further stacked.

The negative electrode 931 is connected to the terminal 911 via one of the terminal 951 and the terminal 952. The positive electrode 932 is connected to the terminal 911 via the other of the terminal 951 and the terminal 952.

This embodiment can be implemented in appropriate combination with any of the other embodiments.

### Embodiment 9

In this embodiment, examples of electronic devices including the secondary battery of one embodiment of the present invention are described

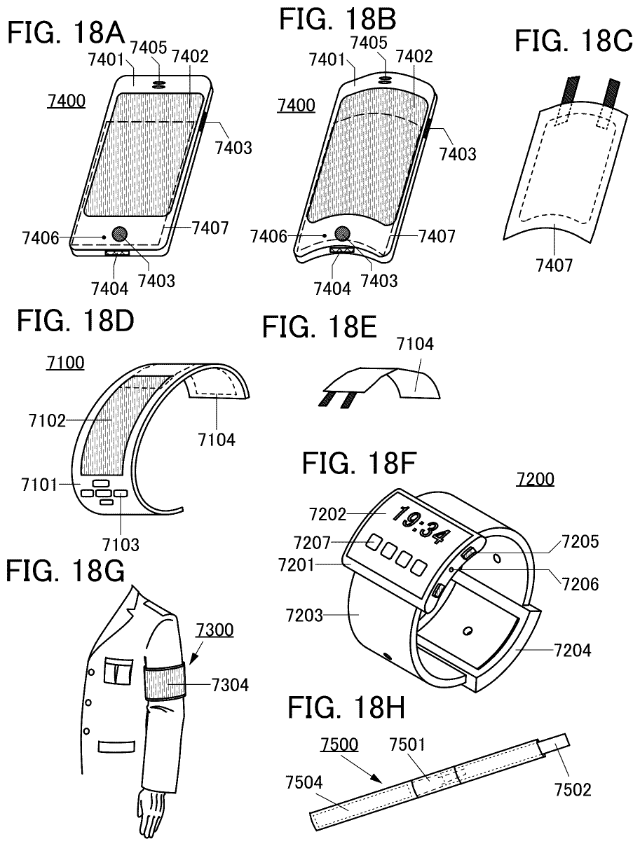

First, examples of electronic devices each including the secondary battery are illustrated in FIG. 18A to FIG. 18G. Examples of the electronic device include a television device (also referred to as a television or a television receiver), a monitor for a computer or the like, a digital camera, a digital video camera, a digital photo frame, a mobile phone (also referred to as a cellular phone or a mobile phone device), a portable game machine, a portable information terminal, an audio reproducing device, and a game machine such as a pachinko machine.

Furthermore, a secondary battery can be incorporated along a curved inside/outside wall surface of a house or a building or a curved interior/exterior surface of an automobile.

FIG. 18A illustrates an example of a mobile phone. A mobile phone 7400 is provided with a display portion 7402 incorporated in a housing 7401, operation buttons 7403, an external connection port 7404, a speaker 7405, a microphone 7406, and the like. Note that the mobile phone 7400 includes a secondary battery 7407. The secondary battery 7407 can be provided with a sensor member.

FIG. 18B illustrates the state where the mobile phone 7400 is curved. When the whole mobile phone 7400 is curved by external force, the secondary battery 7407 provided therein is also curved. FIG. 18C illustrates the bent secondary battery 7407. The secondary battery 7407 is a thin storage battery. The secondary battery 7407 is fixed in a state of being bent. The secondary battery 7407 can be provided with a sensor member.

Note that the secondary battery 7407 includes a lead electrode electrically connected to a current collector. The current collector is, for example, copper foil, and partly alloyed with gallium; thus, adhesion between the current collector and an active material layer in contact with the current collector is improved and the secondary battery 7407 can have high reliability even in a state of being bent.

FIG. 18D illustrates an example of a bangle-type display device. A portable display device 7100 includes a housing 7101, a display portion 7102, operation buttons 7103, and a secondary battery 7104. FIG. 18E illustrates the bent secondary battery 7104. The secondary battery 7104 can be provided with a sensor member.

When the secondary battery 7104 is worn, the housing changes its shape and the curvature of part or the whole of the secondary battery 7104 is changed. Note that the bending condition of a curve at a given point that is represented by a value of the radius of a corresponding circle is referred to as the radius of curvature, and the reciprocal of the radius of curvature is referred to as curvature. Specifically, part or the whole of the housing or the main surface of the secondary battery 7104 is changed in the range of radius of curvature greater than or equal to 40 mm and less than or equal to 150 mm. When the radius of curvature at the main surface of the secondary battery 7104 is in the range greater than or equal to 40 mm and less than or equal to 150 mm, the reliability can be kept high.

FIG. 18F illustrates an example of a watch-type portable information terminal. A portable information terminal 7200 includes a housing 7201, a display portion 7202, a band 7203, a buckle 7204, an operation button 7205, an input/output terminal 7206, and the like.

The portable information terminal 7200 is capable of executing a variety of applications such as mobile phone calls, e-mailing, viewing and editing texts, music reproduction, Internet communication, and computer games.

The display surface of the display portion 7202 is curved, and images can be displayed on the curved display surface. The display portion 7202 includes a touch sensor, and operation can be performed by touching the screen with a finger, a stylus, or the like. For example, by touching an icon 7207 displayed on the display portion 7202, application can be started.

With the operation button 7205, a variety of functions such as time setting, power on/off operation, wireless communication on/off operation, execution and cancellation of a silent mode, and execution and cancellation of a power saving mode can be performed. For example, the functions of the operation button 7205 can be set freely by setting the operating system incorporated in the portable information terminal 7200.

The portable information terminal 7200 can perform near field communication that is standardized communication. For example, mutual communication between the portable information terminal 7200 and a headset capable of wireless communication enables hands-free calling.

The portable information terminal 7200 includes the input/output terminal 7206, and data can be directly transmitted to and received from another information terminal via a connector. In addition, charging via the input/output terminal 7206 is possible. Note that the charge operation may be performed by wireless power feeding without using the input/output terminal 7206.

The display portion 7202 of the portable information terminal 7200 includes the secondary battery of one embodiment of the present invention. For example, the secondary battery 7104 illustrated in FIG. 18E can be provided in the housing 7201 while being curved, or can be provided in the band 7203 such that it can be curved. The secondary battery can be provided with a sensor member.

The portable information terminal 7200 preferably includes a sensor. As the sensor, a human body sensor such as a fingerprint sensor, a pulse sensor, or a temperature sensor, a touch sensor, a pressure sensitive sensor, or an acceleration sensor is preferably incorporated, for example.

FIG. 18G illustrates an example of an armband display device. A display device 7300 includes a display portion 7304 and the secondary battery of one embodiment of the present invention. The secondary battery can be provided with a sensor member. The display device 7300 can include a touch sensor in the display portion 7304 and can serve as a portable information terminal.

The display surface of the display portion 7304 is curved, and images can be displayed on the curved display surface. A display state of the display device 7300 can be changed by, for example, near field communication that is standardized communication.

The display device 7300 includes an input/output terminal, and data can be directly transmitted to and received from another information terminal via a connector. In addition, charging via the input/output terminal is possible. Note that the charge operation may be performed by wireless power feeding without using the input/output terminal.

When the secondary battery of one embodiment of the present invention is used as a secondary battery of a daily electronic device, a lightweight product with a long lifetime can be provided. Examples of the daily electronic device include an electric toothbrush, an electric shaver, and electric beauty equipment. As secondary batteries of these products, small and lightweight stick type secondary batteries with high charge/discharge capacity are desired in consideration of handling ease for users.

FIG. 18H is a perspective view of a device called a vaporizer (electronic cigarette). In FIG. 18H, an electronic cigarette 7500 includes an atomizer 7501 including a heating element, a secondary battery 7504 that supplies electric power to the atomizer, and a cartridge 7502 including a liquid supply bottle, a sensor, and the like. The secondary battery 7504 can be provided with a sensor member. To improve safety, a protection circuit that prevents overcharging and overdischarging of the secondary battery 7504 may be electrically connected to the secondary battery 7504. The secondary battery 7504 illustrated in FIG. 18H includes an external terminal to be connected to a charger. When the electronic cigarette 7500 is held, the secondary battery 7504 is a tip portion; thus, it is preferable that the secondary battery 7504 have a short total length and be lightweight. With the secondary battery of one embodiment of the present invention, which has high charge/discharge capacity and excellent cycle performance, the small and lightweight electronic cigarette 7500 that can be used for a long time over a long period can be provided.

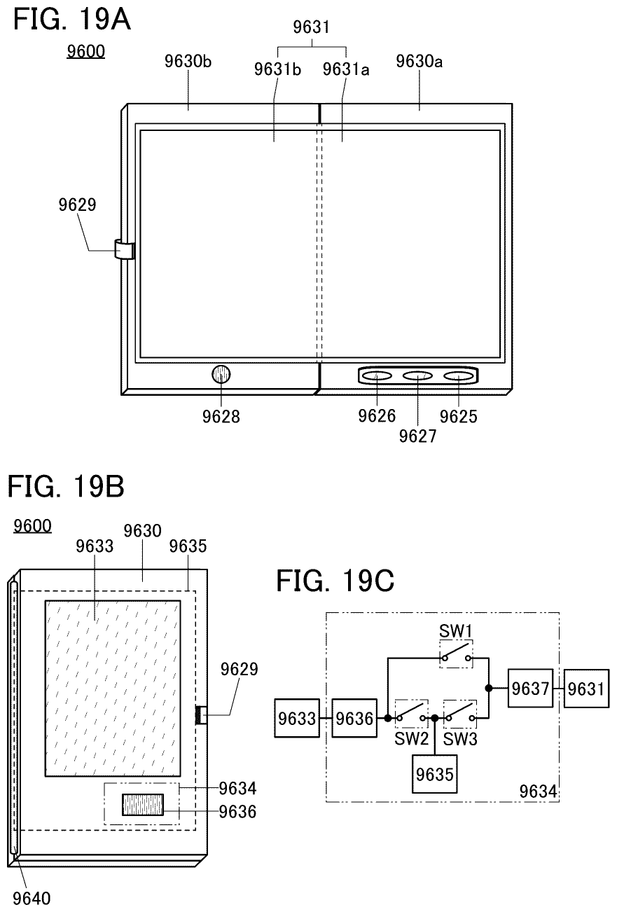

Next, FIG. 19A and FIG. 19B illustrate an example of a foldable tablet terminal. A tablet terminal 9600 illustrated in FIG. 19A and FIG. 19B includes a housing 9630a, a housing 9630b, a movable portion 9640 connecting the housing 9630a and the housing 9630b to each other, a display portion 9631 including a display portion 9631a and a display portion 9631b, a switch 9625 to a switch 9627, a fastener 9629, and an operation switch 9628. When a flexible panel is used for the display portion 9631, the tablet terminal can have a larger display portion. FIG. 19A illustrates the tablet terminal 9600 that is opened, and FIG. 19B illustrates the tablet terminal 9600 that is closed.

The tablet terminal 9600 includes a secondary battery 9635 inside the housing 9630a and the housing 9630b. The secondary battery 9635 is provided across the housing 9630a and the housing 9630b, passing through the movable portion 9640.

The entire region or part of the region of the display portion 9631 can be a touch panel region, and data can be input by touching an image including an icon, text, an input form, or the like displayed on the region. For example, it is possible that keyboard buttons are displayed on the entire display portion 9631a on the housing 9630a side, and data such as text or an image is displayed on the display portion 9631b on the housing 9630b side.

It is possible that a keyboard is displayed on the display portion 9631b on the housing 9630b side, and data such as text or an image is displayed on the display portion 9631a on the housing 9630a side. Furthermore, it is possible that a switching button for showing/hiding a keyboard on a touch panel is displayed on the display portion 9631 and the button is touched with a finger, a stylus, or the like to display a keyboard on the display portion 9631.

Touch input can be performed concurrently in a touch panel region in the display portion 9631a on the housing 9630a side and a touch panel region in the display portion 9631b on the housing 9630b side.

The switch 9625 to the switch 9627 may function not only as an interface for operating the tablet terminal 9600 but also as an interface that can switch various functions. For example, at least one of the switch 9625 to the switch 9627 may function as a switch for switching power on/off of the tablet terminal 9600. For another example, at least one of the switch 9625 to the switch 9627 may have a function of switching display between a portrait mode and a landscape mode or a function of switching display between monochrome display and color display. For another example, at least one of the switch 9625 to the switch 9627 may have a function of adjusting the luminance of the display portion 9631. The luminance of the display portion 9631 can be optimized in accordance with the amount of external light in use of the tablet terminal 9600 detected by an optical sensor incorporated in the tablet terminal 9600. Note that another sensing device including a sensor for sensing inclination, such as a gyroscope sensor or an acceleration sensor, may be incorporated in the tablet terminal, in addition to the optical sensor.

In addition, FIG. 19A illustrates the example where the display portion 9631a on the housing 9630a side and the display portion 9631b on the housing 9630b side have substantially the same display area; however, there is no particular limitation on the display area of each of the display portion 9631a and the display portion 9631b, and one of the display portions and the other thereof may have different sizes or different display quality. For example, one may be a display panel that can display higher-resolution images than the other.

The tablet terminal 9600 is folded in half in FIG. 19B. The tablet terminal 9600 includes a housing 9630, a solar cell 9633, and a charge and discharge control circuit 9634 including a DCDC converter 9636. The secondary battery 9635 can be provided with a sensor member.

Note that as described above, the tablet terminal 9600 can be folded in half, and thus can be folded when not in use such that the housing 9630a and the housing 9630b overlap with each other. The display portion 9631 can be protected when the tablet terminal 9600 is folded, which increases the durability of the tablet terminal 9600. With the secondary battery 9635 employing the secondary battery of one embodiment of the present invention, which has high charge/discharge capacity and excellent cycle performance, the tablet terminal 9600 that can be used for a long time over a long period can be provided.

The tablet terminal 9600 illustrated in FIG. 19A and FIG. 19B can also have a function of displaying various kinds of data (e.g., a still image, a moving image, and a text image), a function of displaying a calendar, the date, or the time on the display portion, a touch-input function of operating or editing data displayed on the display portion by touch input, a function of controlling processing by various kinds of software (programs), and the like.

With the solar cell 9633 that is attached onto the surface of the tablet terminal 9600, electric power can be supplied to a touch panel, a display portion, a video signal processing portion, and the like. Note that it is possible to obtain a structure where the solar cell 9633 can be provided on one surface or both surfaces of the housing 9630 and the secondary battery 9635 is charged efficiently. The use of a lithium-ion battery as the secondary battery 9635 brings an advantage such as a reduction in size.

The structure and operation of the charge and discharge control circuit 9634 illustrated in FIG. 19B are described with reference to a block diagram in FIG. 19C. FIG. 19C illustrates the solar cell 9633, the secondary battery 9635, the DCDC converter 9636, a switch SW1 to a switch SW3, and the display portion 9631, and the secondary battery 9635, the DCDC converter 9636, and the switch SW1 to the switch SW3 correspond to the charge and discharge control circuit 9634 illustrated in FIG. 19B.

First, an operation example in which electric power is generated by the solar cell 9633 using external light is described. The voltage of electric power generated by the solar cell is raised or lowered by the DCDC converter 9636 to be a voltage for charging the secondary battery 9635. Then, when the electric power from the solar cell 9633 is used for the operation of the display portion 9631, the switch SW1 is turned on and the voltage of the electric power is raised or lowered by a converter 9637 to be a voltage needed for the display portion 9631. When display on the display portion 9631 is not performed, SW1 is turned off and SW2 is turned on, so that the secondary battery 9635 can be charged.

Note that the solar cell 9633 is described as an example of a power generation means; however, one embodiment of the present invention is not limited to this example. The secondary battery 9635 may be charged using another power generation means such as a piezoelectric element or a thermoelectric conversion element (Peltier element). For example, the charging may be performed with a non-contact power transmission module that performs charging by transmitting and receiving electric power wirelessly (without contact), or with a combination of other charge units.

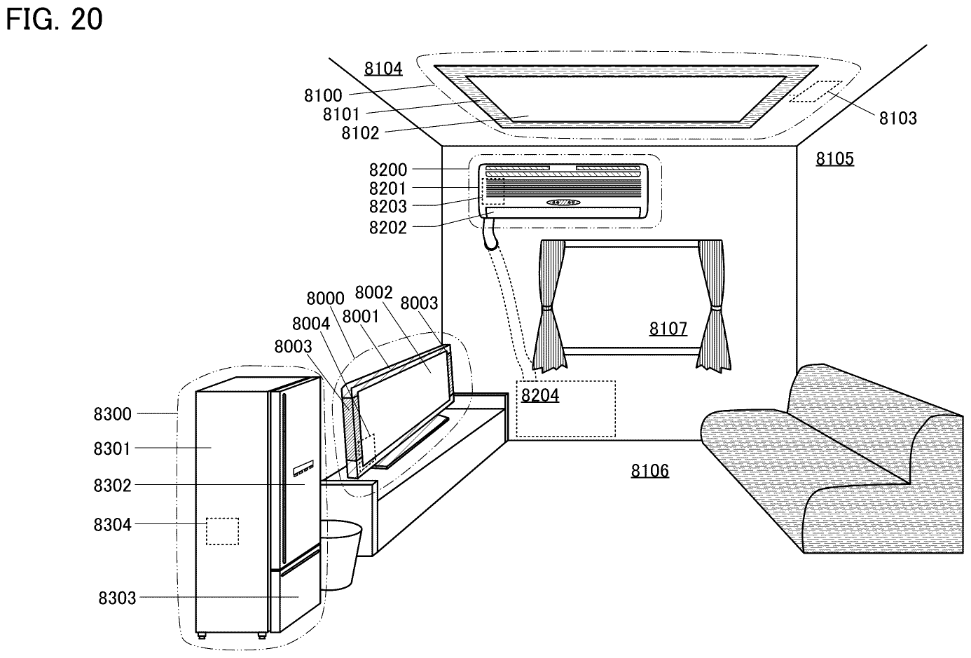

FIG. 20 illustrates other examples of electronic devices. In FIG. 20, a display device 8000 is an example of an electronic device using a secondary battery 8004 of one embodiment of the present invention. Specifically, the display device 8000 corresponds to a display device for TV broadcast reception and includes a housing 8001, a display portion 8002, speaker portions 8003, the secondary battery 8004, and the like. The secondary battery 8004 can be provided with a sensor portion. The display device 8000 can be supplied with electric power from a commercial power source and can use electric power stored in the secondary battery 8004. Thus, the display device 8000 can be operated with the use of the secondary battery 8004 of one embodiment of the present invention as an uninterruptible power source even when electric power cannot be supplied from a commercial power source due to power failure or the like.

A semiconductor display device such as a liquid crystal display device, a light-emitting device in which a light-emitting element such as an organic EL element is provided in each pixel, an electrophoresis display device, a DMD (Digital Micromirror Device), a PDP (Plasma Display Panel), or an FED (Field Emission Display) can be used for the display portion 8002.

Note that the display device includes, in its category, all of information display devices for personal computers, advertisement displays, and the like besides information display devices for TV broadcast reception.

In an installation lighting device 8100 in FIG. 20, a secondary battery 8103 can be provided with a sensor member. Specifically, the lighting device 8100 includes a housing 8101, a light source 8102, the secondary battery 8103, and the like. Although FIG. 20 illustrates the case where the secondary battery 8103 is provided in a ceiling 8104 on which the housing 8101 and the light source 8102 are installed, the secondary battery 8103 may be provided in the housing 8101. The lighting device 8100 can be supplied with electric power from a commercial power source and can use electric power stored in the secondary battery 8103. Thus, the lighting device 8100 can be operated with the use of the secondary battery 8103 of one embodiment of the present invention as an uninterruptible power source even when electric power cannot be supplied from a commercial power source due to power failure or the like.

Note that although the installation lighting device 8100 provided in the ceiling 8104 is illustrated in FIG. 20 as an example, the secondary battery of one embodiment of the present invention can be used in an installation lighting device provided in, for example, a sidewall 8105, a floor 8106, a window 8107, or the like other than the ceiling 8104. The secondary battery can also be used in a tabletop lighting device or the like. The secondary battery can be provided with a sensor member.

As the light source 8102, an artificial light source that emits light artificially by using electric power can be used. Specifically, an incandescent lamp, a discharge lamp such as a fluorescent lamp, and a light-emitting element such as an LED or an organic EL element are given as examples of the artificial light source.

In FIG. 20, an air conditioner including an indoor unit 8200 and an outdoor unit 8204 includes the secondary battery 8203 of one embodiment of the present invention, and the secondary battery 8203 can be provided with a sensor member. Specifically, the indoor unit 8200 of the air conditioner includes a housing 8201, an air outlet 8202, the secondary battery 8203, and the like. Although FIG. 20 illustrates the case where the secondary battery 8203 is provided in the indoor unit 8200, the secondary battery 8203 may be provided in the outdoor unit 8204. Alternatively, the secondary batteries 8203 may be provided in both the indoor unit 8200 and the outdoor unit 8204. The air conditioner can be supplied with electric power from a commercial power source and can use electric power stored in the secondary battery 8203. Particularly in the case where the secondary batteries 8203 are provided in both the indoor unit 8200 and the outdoor unit 8204, the air conditioner can be operated with the use of the secondary battery 8203 of one embodiment of the present invention as an uninterruptible power source even when electric power cannot be supplied from a commercial power source due to power failure or the like.

Note that although the split-type air conditioner including the indoor unit and the outdoor unit is illustrated in FIG. 20 as an example, the secondary battery of one embodiment of the present invention can also be used in an air conditioner in which the functions of an indoor unit and an outdoor unit are integrated in one housing.

In FIG. 20, an electric refrigerator-freezer 8300 is an example of an electronic device that uses a secondary battery 8304 of one embodiment of the present invention, and the secondary battery 8304 can be provided with a sensor member. Specifically, the electric refrigerator-freezer 8300 includes a housing 8301, a refrigerator door 8302, a freezer door 8303, the secondary battery 8304, and the like. The secondary battery 8304 is provided in the housing 8301 in FIG. 20. The electric refrigerator-freezer 8300 can be supplied with electric power from a commercial power source and can use electric power stored in the secondary battery 8304. Thus, the electric refrigerator-freezer 8300 can be operated with the use of the secondary battery 8304 of one embodiment of the present invention as an uninterruptible power source even when electric power cannot be supplied from a commercial power source due to power failure or the like.

Note that among the electronic devices described above, a high-frequency heating apparatus such as a microwave oven and an electronic device such as an electric rice cooker require high electric power in a short time. Therefore, the tripping of a breaker of a commercial power source in use of the electronic device can be prevented by using the secondary battery of one embodiment of the present invention as an auxiliary power source for supplying electric power which cannot be supplied enough by a commercial power source.

In a time period when electronic devices are not used, particularly when the proportion of the amount of electric power which is actually used to the total amount of electric power which can be supplied from a commercial power supply source (such a proportion is referred to as a usage rate of electric power) is low, electric power is stored in the secondary battery, whereby an increase in the usage rate of electric power can be inhibited in a time period other than the above time period. For example, in the case of the electric refrigerator-freezer 8300, electric power is stored in the secondary battery 8304 in night time when the temperature is low and the refrigerator door 8302 and the freezer door 8303 are not opened or closed. Moreover, in daytime when the temperature is high and the refrigerator door 8302 and the freezer door 8303 are opened and closed, the usage rate of electric power in daytime can be kept low by using the secondary battery 8304 as an auxiliary power source.

According to one embodiment of the present invention, the secondary battery can have excellent cycle performance and improved reliability. Furthermore, according to one embodiment of the present invention, a secondary battery with high charge/discharge capacity can be obtained; thus, the secondary battery itself can be made more compact and lightweight as a result of improved characteristics of the secondary battery. Thus, the secondary battery of one embodiment of the present invention is provided in the electronic device described in this embodiment, whereby a more lightweight electronic device with a longer lifetime can be obtained.

This embodiment can be implemented in appropriate combination with the other embodiments.

### Embodiment 10

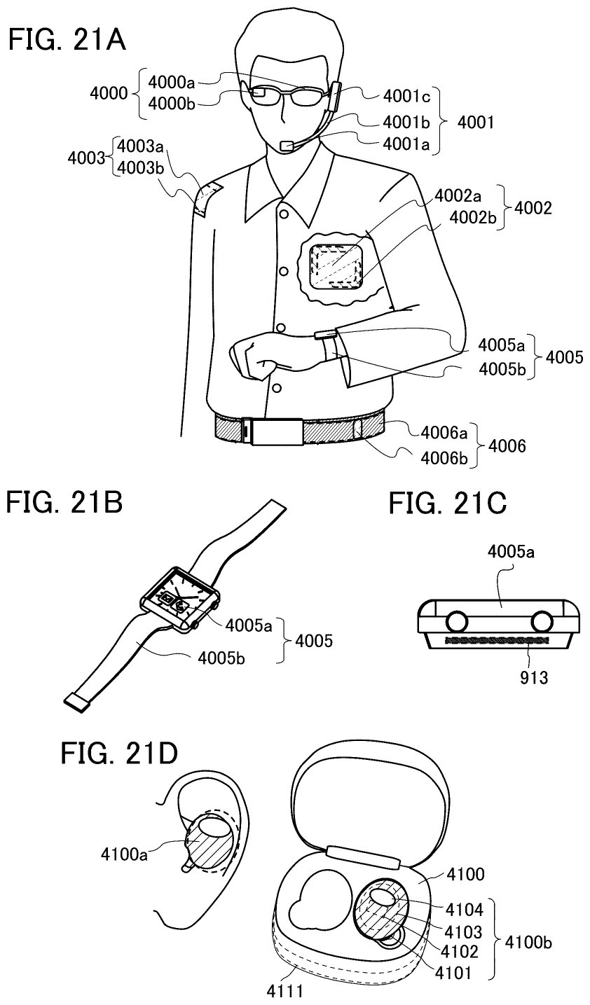

In this embodiment, examples of electronic devices each including the secondary battery described in the above embodiment are described with reference to FIG. 21A and FIG. 21D.

FIG. 21A illustrates examples of wearable devices. A secondary battery is used as a power source of a wearable device, and the secondary battery can be provided with a sensor member. To have improved splash resistance, water resistance, or dust resistance in daily use or outdoor use by a user, a wearable device is desirably capable of being charged with and without a wire whose connector portion for connection is exposed.

For example, the secondary battery of one embodiment of the present invention can be provided in a glasses-type device 4000 illustrated in FIG. 21A, and the secondary battery can be provided with a sensor member. The glasses-type device 4000 includes a frame 4000a and a display portion 4000b. The secondary battery is provided in a temple of the frame 4000a having a curved shape, whereby the glasses-type device 4000 can be lightweight, can have a well-balanced weight, and can be used continuously for a long time. With the use of the secondary battery of one embodiment of the present invention, space saving required with downsizing of a housing can be achieved.

The secondary battery of one embodiment of the present invention can be provided in a headset-type device 4001, and the secondary battery can be provided with a sensor member. The headset-type device 4001 includes at least a microphone part 4001a, a flexible pipe 4001b, and an earphone portion 4001c. The secondary battery can be provided in the flexible pipe 4001b or the earphone portion 4001c. With the use of the secondary battery of one embodiment of the present invention, space saving required with downsizing of a housing can be achieved.

The secondary battery of one embodiment of the present invention can be provided in a device 4002 that can be attached directly to a body, and the secondary battery can be provided with a sensor member. A secondary battery 4002b can be provided in a thin housing 4002a of the device 4002. With the use of the secondary battery of one embodiment of the present invention, space saving required with downsizing of a housing can be achieved.

The secondary battery of one embodiment of the present invention can be provided in a device 4003 that can be attached to clothes, and the secondary battery can be provided with a sensor member. A secondary battery 4003b can be provided in a thin housing 4003a of the device 4003. With the use of the secondary battery of one embodiment of the present invention, space saving required with downsizing of a housing can be achieved.

The secondary battery of one embodiment of the present invention can be provided in a belt-type device 4006, and the secondary battery can be provided with a sensor member. The belt-type device 4006 includes a belt portion 4006a and a wireless power feeding and receiving portion 4006b, and the secondary battery can be provided inside the belt portion 4006a. With the use of the secondary battery of one embodiment of the present invention, space saving required with downsizing of a housing can be achieved.

The secondary battery of one embodiment of the present invention can be provided in a watch-type device 4005, and the secondary battery can be provided with a sensor member. The watch-type device 4005 includes a display portion 4005a and a belt portion 4005b, and the secondary battery can be provided in the display portion 4005a or the belt portion 4005b. With the use of the secondary battery of one embodiment of the present invention, space saving required with downsizing of a housing can be achieved.

The display portion 4005a can display various kinds of information such as time and reception information of an e-mail and/or an incoming call.

The watch-type device 4005 is a wearable device that is wound around an arm directly; thus, a sensor that measures the pulse, the blood pressure, or the like of the user may be incorporated therein. Data on the exercise quantity and health of the user can be stored to be used for health maintenance.

FIG. 21B illustrates a perspective view of the watch-type device 4005 that is detached from an arm.

FIG. 21C is a side view. FIG. 21C illustrates a state where a secondary battery 913 is incorporated inside. The secondary battery 913 is the secondary battery described in the above embodiment. The secondary battery 913, which is small and lightweight, is provided at a position overlapping with the display portion 4005a.

FIG. 21D illustrates an example of wireless earphones. The wireless earphones illustrated here as an example consist of, but not limited to, a pair of main bodies 4100a and 4100b.

The main bodies 4100a and 4100b each include a driver unit 4101, an antenna 4102, and a secondary battery 4103. A display portion 4104 may also be included. Moreover, a substrate where a circuit such as a wireless IC is provided, a terminal for charging, and the like are preferably included. Furthermore, a microphone may be included.

A case 4100 includes a secondary battery 4111. Moreover, a substrate where a circuit such as a wireless IC or a charge control IC is provided, and a terminal for charging are preferably included. Furthermore, a display portion, a button, and the like may be included.

The main bodies 4100a and 4100b can communicate wirelessly with another electronic device such as a smartphone. Thus, sound data and the like transmitted from another electronic device can be played through the main bodies 4100a and 4100b. When the main bodies 4100a and 4100b include a microphone, sound captured by the microphone is transmitted to another electronic device, and sound data obtained by processing with the electronic device can be transmitted to and played through the main bodies 4100a and 4100b. Hence, the wireless earphones can be used as a translator, for example.

The secondary battery 4103 included in the main body 4100a can be charged by the secondary battery 4111 included in the case 4100. The coin-type secondary battery, the cylindrical secondary battery, or the like of the above embodiment can be used as the secondary battery 4111 and the secondary battery 4103, and the secondary battery 4111 and the secondary battery 4103 can be provided with a sensor member. A secondary battery using the positive electrode active material 100 for a positive electrode has a high energy density, and thus can achieve, when used as the secondary battery 4103 and the secondary battery 4111, a structure that accommodates space saving required with downsizing of the wireless earphones.

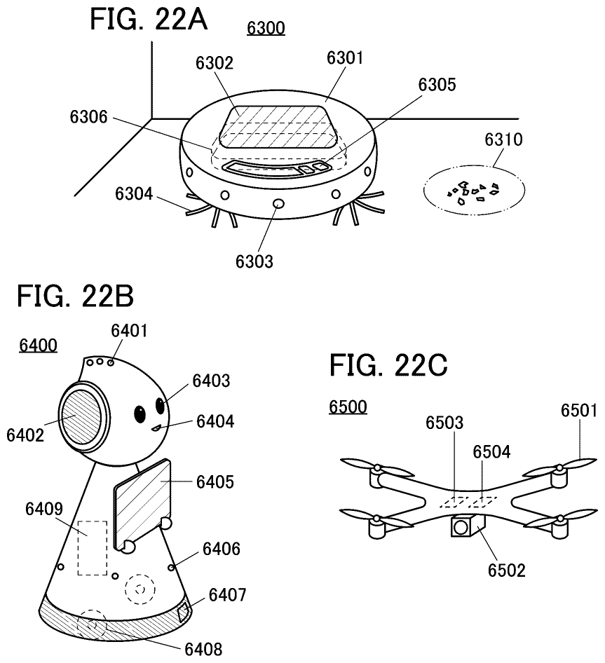

FIG. 22A illustrates an example of a cleaning robot. A cleaning robot 6300 includes a display portion 6302 placed on the top surface of a housing 6301, a plurality of cameras 6303 placed on the side surface of the housing 6301, a brush 6304, operation buttons 6305, a secondary battery 6306, a variety of sensors, and the like. Although not illustrated, the cleaning robot 6300 is provided with a tire, an inlet, and the like. The cleaning robot 6300 is self-propelled, detects dust 6310, and sucks up the dust through the inlet provided on the bottom surface.

For example, the cleaning robot 6300 can determine whether there is an obstacle such as a wall, furniture, or a step by analyzing images taken by the cameras 6303. In the case where the cleaning robot 6300 detects an object, such as a wire, that is likely to be caught in the brush 6304 by image analysis, the rotation of the brush 6304 can be stopped. The cleaning robot 6300 further includes a secondary battery 6306 of one embodiment of the present invention and a semiconductor device or an electronic component. The secondary battery 6306 can be provided with a sensor member. The cleaning robot 6300 including the secondary battery 6306 of one embodiment of the present invention can be a highly reliable electronic device that can operate for a long time.

FIG. 22B illustrates an example of a robot. A robot 6400 illustrated in FIG. 22B includes a secondary battery 6409, an illuminance sensor 6401, a microphone 6402, an upper camera 6403, a speaker 6404, a display portion 6405, a lower camera 6406, an obstacle sensor 6407, a moving mechanism 6408, an arithmetic device, and the like.

The microphone 6402 has a function of detecting a speaking voice of a user, an environmental sound, and the like. The speaker 6404 has a function of outputting sound. The robot 6400 can communicate with the user using the microphone 6402 and the speaker 6404.

The display portion 6405 has a function of displaying various kinds of information. The robot 6400 can display information desired by the user on the display portion 6405. The display portion 6405 may be provided with a touch panel. Moreover, the display portion 6405 may be a detachable information terminal, in which case charging and data communication can be performed when the display portion 6405 is set at the home position of the robot 6400.

The upper camera 6403 and the lower camera 6406 each have a function of taking an image of the surroundings of the robot 6400. The obstacle sensor 6407 can detect an obstacle in the direction where the robot 6400 advances with the moving mechanism 6408. The robot 6400 can move safely by recognizing the surroundings with the upper camera 6403, the lower camera 6406, and the obstacle sensor 6407.

The robot 6400 further includes the secondary battery 6409 of one embodiment of the present invention and a semiconductor device or an electronic component. The robot 6400 including the secondary battery of one embodiment of the present invention can be a highly reliable electronic device that can operate for a long time.

FIG. 22C illustrates an example of a flying object. A flying object 6500 illustrated in FIG. 22C includes propellers 6501, a camera 6502, a secondary battery 6503, and the like and has a function of flying autonomously.

For example, image data taken by the camera 6502 is stored in an electronic component 6504. The electronic component 6504 can analyze the image data to detect whether there is an obstacle in the way of the movement. Moreover, the electronic component 6504 can estimate the remaining battery level from a change in the power storage capacity of the secondary battery 6503. The flying object 6500 further includes the secondary battery 6503 of one embodiment of the present invention. When the secondary battery of one embodiment of the present invention is used for the flying object 6500, the flying object 6500 can be a highly reliable electronic device that can operate for a long time. The secondary battery 6503 can be provided with a sensor member.

This embodiment can be implemented in appropriate combination with the other embodiments.

### Embodiment 11

In this embodiment, examples of vehicles each including the secondary battery of one embodiment of the present invention are described.

The use of secondary batteries in vehicles enables production of next-generation clean energy vehicles such as hybrid electric vehicles (HVs), electric vehicles (EVs), or plug-in hybrid electric vehicles (PHVs).

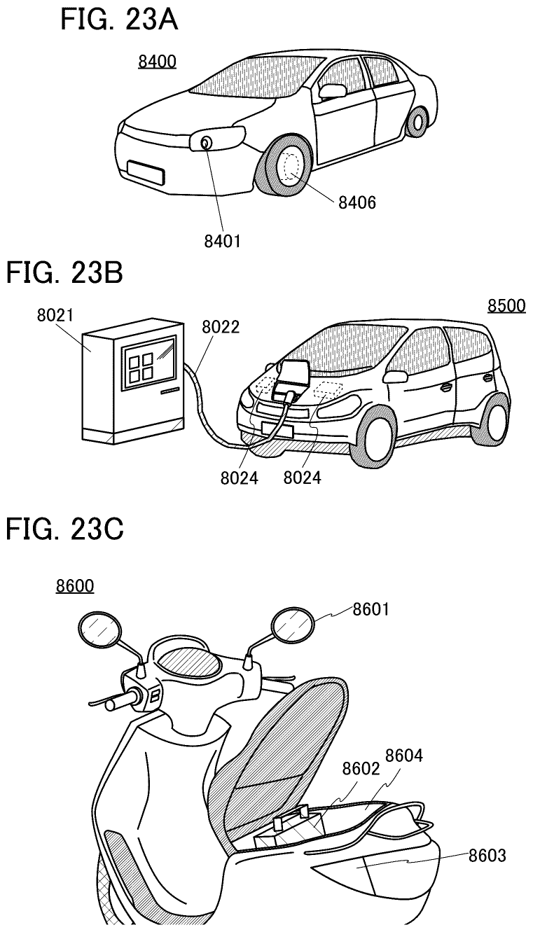

FIG. 23A to FIG. 23C illustrate examples of vehicles each using the secondary battery of one embodiment of the present invention. An automobile 8400 illustrated in FIG. 23A is an electric vehicle that runs on the power of an electric motor. Alternatively, the automobile 8400 is a hybrid electric vehicle capable of driving appropriately using either an electric motor or an engine as a power source. The use of one embodiment of the present invention can achieve a high-mileage vehicle. The automobile 8400 includes the secondary battery. The secondary battery can be used not only for driving an electric motor 8406, but also for supplying electric power to a light-emitting device such as a headlight 8401 or a room light (not illustrated). The secondary battery can be provided with a sensor member.

The secondary battery can also supply electric power to a display device included in the automobile 8400, such as a speedometer or a tachometer. Furthermore, the secondary battery can supply electric power to a semiconductor device included in the automobile 8400, such as a navigation system.

An automobile 8500 illustrated in FIG. 23B can be charged when a secondary battery included in the automobile 8500 is supplied with electric power from external charging equipment by a plug-in system, a contactless power feeding system, or the like. FIG. 23B illustrates a state where a secondary battery 8024 provided in the automobile 8500 is charged from a ground installation type charging apparatus 8021 through a cable 8022. In charging, a given method such as CHAdeMO (registered trademark) or Combined Charging System may be employed as a charging method, the standard of a connector, or the like as appropriate. The charging apparatus 8021 may be a charging station provided in a commerce facility or a power source in a house. For example, with the use of a plug-in technique, the secondary battery 8024 provided in the automobile 8500 can be charged by being supplied with electric power from outside. The charging can be performed by converting AC electric power into DC electric power through a converter such as an ACDC converter.

Although not illustrated, the vehicle may include a power receiving device so that it can be charged by being supplied with electric power from an above-ground power transmitting device in a contactless manner. In the case of the contactless power feeding system, by fitting a power transmitting device in a road or an exterior wall, charging can be performed not only when the vehicle is stopped but also when driven. In addition, the contactless power feeding system may be utilized to perform transmission and reception of electric power between vehicles. Furthermore, a solar cell may be provided in the exterior of the vehicle to charge the secondary battery when the vehicle stops or moves. To supply electric power in such a contactless manner, an electromagnetic induction method or a magnetic resonance method can be used.

In addition, FIG. 23C is an example of a motorcycle using a secondary battery 8602 of one embodiment of the present invention. The secondary battery 8602 can be provided with a sensor member. A motor scooter 8600 illustrated in FIG. 23C includes the secondary battery 8602, side mirrors 8601, and direction indicators 8603. The secondary battery 8602 can supply electric power to the direction indicators 8603.

Furthermore, in the motor scooter 8600 illustrated in FIG. 23C, the secondary battery 8602 can be stored in an under-seat storage 8604. The secondary battery 8602 can be held in the under-seat storage 8604 even when the under-seat storage 8604 is small. The secondary battery 8602 is detachable; thus, the secondary battery 8602 is carried indoors when charged, and is stored before the motor scooter is driven.

According to one embodiment of the present invention, the secondary battery can have improved cycle performance and the charge/discharge capacity of the secondary battery can be increased. Thus, the secondary battery itself can be made more compact and lightweight. The compact and lightweight secondary battery contributes to a reduction in the weight of a vehicle, and thus increases the mileage. Furthermore, the secondary battery provided in the vehicle can be used as a power source for supplying electric power to products other than the vehicle. In this case, the use of a commercial power supply can be avoided at peak time of electric power demand, for example. Avoiding the use of a commercial power supply at peak time of electric power demand can contribute to energy saving and a reduction in carbon dioxide emissions. Moreover, the secondary battery with excellent cycle performance can be used over a long period; thus, the use amount of rare metals typified by cobalt can be reduced.

This embodiment can be implemented in appropriate combination with the other embodiments.

### REFERENCE NUMERALS

11: charge and discharge control portion, 12: current monitor circuit, 13: voltage monitor circuit, 14: current control circuit, 20: charger, 21: protection circuit portion, 22: processor, 23: temperature monitor circuit, 30: impedance measurement portion, 31: interface, 32a: first measurement circuit, 32c: third measurement circuit, 32: measurement circuit, 40: battery unit, 41a: secondary battery, 41c: secondary battery, 42a: thermistor, 42c: thermistor, 50: output portion, 51: USB power supply control circuit, 52: current switching circuit, 53: current blocking circuit, 60: storage battery system, 70: electronic device, 100: positive electrode active material, 110: piezoelectric braid, 111: resistor, 112: capacitor, 113: operational amplifier, 150: first conductive fiber, 151: piezoelectric fiber, 152: second conductive fiber, 160: detection circuit, 200: positive electrode active material layer, 201: conductive material, 300: secondary battery, 301: positive electrode can, 302: negative electrode can, 303: gasket, 304: positive electrode, 305: positive electrode current collector, 306: positive electrode active material layer, 307: negative electrode, 308: negative electrode current collector, 309: negative electrode active material layer, 310: separator, 500: secondary battery, 501: positive electrode tab, 503: positive electrode, 504: adhesive region, 506: negative electrode, 507: separator, 509: exterior body, 510a: first region, 510b: second region, 510: sensor member, 511a: sensor member, 511b: sensor member, 512: negative electrode tab, 600: secondary battery, 601: positive electrode cap, 602: battery can, 603: positive electrode terminal, 604: positive electrode, 605: separator, 606: negative electrode, 607: negative electrode terminal, 608: insulating plate, 609: insulating plate, 611: PTC element, 612: safety valve mechanism, 613: conductive plate, 614: conductive plate, 615: module, 616: wiring, 617: temperature control device, 900: circuit board, 903: mixture, 904: mixture, 910: label, 911: terminal, 912: circuit, 913: secondary battery, 914: antenna, 915: seal, 916: layer, 917: layer, 918: antenna, 920: display device, 921: sensor, 922: terminal, 930a: housing, 930b: housing, 930: housing, 931: negative electrode, 932: positive electrode, 933: separator, 950: wound body, 951: terminal, 952: terminal, 4000a: frame, 4000b: display portion, 4000: glasses-type device, 4001a: microphone portion, 4001b: flexible pipe, 4001c: earphone portion, 4001: headset-type device, 4002a: housing, 4002b: secondary battery, 4002: device, 4003a: housing, 4003b: secondary battery, 4003: device, 4005a: display portion, 4005b: belt portion, 4005: watch-type device, 4006a: belt portion, 4006b: wireless power feeding and receiving portion, 4006: belt-type device, 4100a: main body, 4100b: main body, 4100: case, 4101: driver unit, 4102: antenna, 4103: secondary battery, 4104: display portion, 4110: case, 4111: secondary battery, 6300: cleaning robot, 6301: housing, 6302: display portion, 6303: camera, 6304: brush, 6305: operation button, 6306: secondary battery, 6310: dust, 6400: robot, 6401: illuminance sensor, 6402: microphone, 6403: upper camera, 6404: speaker, 6405: display portion, 6406: lower camera, 6407: obstacle sensor, 6408: moving mechanism, 6409: secondary battery, 6500: flying object, 6501: propeller, 6502: camera, 6503: secondary battery, 6504: electronic component, 7100: display device, 7101: housing, 7102: display portion, 7103: operation button, 7104: secondary battery, 7200: portable information terminal, 7201: housing, 7202: display portion, 7203: band, 7204: buckle, 7205: operation button, 7206: input/output terminal, 7207: icon, 7300: display device, 7304: display portion, 7400: mobile phone, 7401: housing, 7402: display portion, 7403: operation button, 7404: external connection port, 7405: speaker, 7406: microphone, 7407: secondary battery, 7500: electronic cigarette, 7501: atomizer, 7502: cartridge, 7504: secondary battery, 8000: display device, 8001: housing, 8002: display portion, 8003: speaker portion, 8004: secondary battery, 8021: charging apparatus, 8022: cable, 8024: secondary battery, 8100: lighting device, 8101: housing, 8102: light source, 8103: secondary battery, 8104: ceiling, 8105: sidewall 8106: floor, 8107: window, 8200: indoor unit, 8201: housing, 8202: air outlet, 8203: secondary battery, 8204: outdoor unit, 8300: electric refrigerator-freezer, 8301: housing, 8302: refrigerator door, 8303: freezer door, 8304: secondary battery, 8400: automobile, 8401: head light, 8406: electric motor, 8500: automobile, 8600: motor scooter, 8601: side mirror, 8602: secondary battery, 8603: direction indicator, 8604: under-seat storage, 9600: tablet terminal, 9625: switch, 9627: switch, 9628: operation switch, 9629: buckle, 9630a: housing, 9630b: housing, 9630: housing, 9631a: display portion, 9631b: display portion, 9631: display portion, 9633: solar cell, 9634: charge and discharge control circuit, 9635: secondary battery, 9636: DCDC converter, 9637: converter, 9640: movable portion

1. A storage battery system comprising a first secondary battery and a second secondary battery each comprising an exterior body holding an electrolyte solution, a positive electrode, and a negative electrode; a sensor member provided to be in contact with part of the exterior body; and a detection circuit electrically connected to the sensor member,
wherein the first secondary battery comprises a memory unit storing data collected with gas introduction into the second secondary battery, a learning model constructed on the basis of the data, and an estimated value obtained using the learning model; and a unit providing information based on the estimated value.

2. A storage battery system comprising a first secondary battery and a second secondary battery each comprising an exterior body holding an electrolyte solution, a positive electrode, and a negative electrode; a sensor member provided to be in contact with part of the exterior body; and a detection circuit electrically connected to the sensor member,
wherein the first secondary battery comprises a memory unit storing an expansion amount collected with gas introduction into the second secondary battery, a learning model constructed on the basis of the expansion amount, an estimated value obtained using the learning model; and a unit providing information based on the estimated value.

3. The storage battery system according to claim 1,
wherein the electrolyte solution comprises an organic solvent.

4. The storage battery system according to claim 1,
wherein the sensor member is a film-like or string-like piezoelectric element.

5. A secondary battery comprising an exterior body holding an electrolyte solution, a positive electrode, and a negative electrode; a sensor member provided to be in contact with part of the exterior body; and a detection circuit electrically connected to the sensor member.

6. The secondary battery according to claim 5,
wherein the sensor member is a film-like or string-like piezoelectric element.

7. A method for operating a storage battery system,
the storage battery system comprising a first secondary battery and a second secondary battery each comprising an exterior body holding an electrolyte solution, a positive electrode, and a negative electrode; a sensor member provided to be in contact with part of the exterior body; and a detection circuit electrically connected to the sensor member,
the method comprising:
a step of introducing a gas into the second secondary battery;
a step of collecting data on the second secondary battery;
a step of constructing a learning model on the basis of the data;
a step of storing an estimated value obtained using the learning model; and
a step of providing information based on the estimated value to the first secondary battery.

8. A method for operating a storage battery system,
the storage battery system comprising a first secondary battery and a second secondary battery each comprising an exterior body holding an electrolyte solution, a positive electrode, and a negative electrode; a sensor member provided to be in contact with part of the exterior body; and a detection circuit electrically connected to the sensor member,
the method comprising:
a step of introducing a gas into the second secondary battery and expanding the second secondary battery;
a step of collecting an expansion amount of the second secondary battery;
a step of constructing a learning model on the basis of the expansion amount;
a step of storing an estimated value obtained using the learning model; and
a step of providing information based on the estimated value to the first secondary battery.

9. The method for operating the storage battery system, according to claim 7,
wherein the electrolyte solution comprises an organic solvent.

10. The method for operating the storage battery system, according to claim 7,
wherein the sensor member is a film-like or string-like piezoelectric element.

11. The storage battery system according to claim 2,
wherein the electrolyte solution comprises an organic solvent.

12. The storage battery system according to claim 2,
wherein the sensor member is a film-like or string-like piezoelectric element.

13. The storage battery system according to claim 3,
wherein the sensor member is a film-like or string-like piezoelectric element.

14. The method for operating the storage battery system, according to claim 8,
wherein the electrolyte solution comprises an organic solvent.

15. The method for operating the storage battery system, according to claim 8,
wherein the sensor member is a film-like or string-like piezoelectric element.

16. The method for operating the storage battery system, according to claim 9,
wherein the sensor member is a film-like or string-like piezoelectric element.
